(19) United States
(12) Patent Application Publication
(10) Pub. No.: US 2012/0327714 A1
(43) Pub. Date: Dec. 27, 2012

(54) Memory Architecture of 3D Array With Diode in Memory String

(75) Inventor: Hang-Ting Lue, Hsinchu (TW)

(73) Assignee: Macronix International Co., Ltd., Hsinchu (TW)

(21) Appl. No.: 13/363,014

(22) Filed: Jan. 31, 2012

Related U.S. Application Data
(60) Provisional application No. 61/500,484, filed on Jun. 23, 2011.

(51) Int. Cl. G11C 16/04

(52) U.S. Cl. 365/185.17

(57) ABSTRACT

Various embodiments are directed to 3D memory arrays that lack a select line and devices controlled by the select line between one of the source line and the bit line, and the memory cells. Diodes between the other of source line and the bit line, and the memory cells provide needed isolation from the memory cells.

### REFERENCE TO RELATED APPLICATION

This application claims the benefit of U.S. Provisional Patent Application No. 61/500,484 filed 23 Jun. 2011, which is incorporated herein by reference.

### BACKGROUND OF THE INVENTION

1. Field of the Invention

The present invention relates to high density memory devices, and particularly to memory devices in which multiple planes of memory cells are arranged to provide a three-dimensional 3D array.

2. Description of Related Art

As critical dimensions of devices in integrated circuits shrink to the limits of common memory cell technologies, designers have been looking to techniques for stacking multiple planes of memory cells to achieve greater storage capacity, and to achieve lower costs per bit. For example, thin film transistor techniques are applied to charge trapping memory technologies in Lai, et al., “A Multi-Layer Stackable Thin-Film Transistor (TFT) NAND-Type Flash Memory,” IEEE Int'l Electron Devices Meeting, 11-13 Dec. 2006; and in Jung et al., “Three Dimensionally Stacked NAND Flash Memory Technology Using Stacking Single Crystal Si Layers on ILD and TANOS Structure for Beyond 30 nm Node”, IEEE Int'l Electron Devices Meeting, 11-13 Dec. 2006.

Also, cross-point array techniques have been applied for anti-fuse memory in Johnson et al., “512-Mb PROM With a Three-Dimensional Array of Diode/Anti-fuse Memory Cells” IEEE J. of Solid-State Circuits, vol. 38, no. 11, November 2003. In the design described in Johnson et al., multiple layers of word lines and bit lines are provided, with memory elements at the cross-points. The memory elements comprise a p+ polysilicon anode connected to a word line, and an n-polysilicon cathode connected to a bit line, with the anode and cathode separated by anti-fuse material.

In the processes described in Lai, et al., Jung, et al. and Johnson et al., there are several critical lithography steps for each memory layer. Thus, the number of critical lithography steps needed to manufacture the device is multiplied by the number of layers that are implemented. So, although the benefits of higher density are achieved using 3D arrays, the higher manufacturing costs limit the use of the technology.

Another structure that provides vertical NAND cells in a charge trapping memory technology is described in Tanaka et al., “Bit Cost Scalable Technology with Punch and Plug Process for Ultra High Density Flash Memory”, 2007 Symposium on VLSI Technology Digest of Technical Papers; 12-14 Jun. 2007, pages: 14-15. The structure described in Tanaka et al. includes a multi-gate field effect transistor structure having a vertical channel which operates like a NAND gate, using silicon-oxide-nitride-oxide-silicon SONOS charge trapping technology to create a storage site at each gate/vertical channel interface. The memory structure is based on a pillar of semiconductor material arranged as the vertical channel for the multi-gate cell, with a lower select gate adjacent the substrate, and an upper select gate on top. A plurality of horizontal control gates is formed using planar electrode layers that intersect with the pillars. The planar electrode layers used for the control gates do not require critical lithography, and thereby save costs. However, many critical lithography steps are required for each of the vertical cells. Also, there is a limit in the number of control gates that can be layered in this way, determined by such factors as the conductivity of the vertical channel, program and erase processes that are used and so on.

U.S. Provisional Application No. 61/379,297, filed on 1 Sep. 2010 and U.S. Provisional Application No. 61/434,685, filed on 20 Jan. 2011, and U.S. application Ser. No. 12/011,717 filed on 21 Jan. 2011 are directed to vertical NAND cells; all applications are incorporated herein by reference. These applications show a memory array with both a source line and a ground select line with corresponding select devices on both ends of the NAND strings.

It is desirable to provide a structure for three-dimensional integrated circuit memory with a low manufacturing cost, including reliable, very small memory elements.

### SUMMARY OF THE INVENTION

Various embodiments are directed to 3D memory arrays that lack a select line and devices controlled by the select line between the source line and the memory cells. Select devices isolate the NAND memory cell string from a bit line or source line. The 3D memory arrays have stacks of NAND memory cell strings between a source line end and a bit line end. At the source line end of the NAND memory cell strings, source lines are coupled to different plane positions of the stacks of NAND memory cell strings. At the bit line end of the NAND memory cell strings, bit lines are coupled to different stacks of NAND memory cell strings. GSL ground select line-controlled transistors selectively isolate the source line end of the NAND string from the source line. SSL string select line-controlled transistors selectively isolate the bit line end of the NAND string from the bit line.

Diodes positioned by the source line end of the NAND string perform electrical isolation between the source line end of the NAND string and the source line. With the diodes performing such electrical isolation, the GSL ground select line-controlled transistors are not required to selectively isolate the source line end of the NAND string from the source line.

One aspect is a memory device, with an integrated circuit substrate and a 3D array of nonvolatile memory cells on the integrated circuit substrate.

The 3D array includes stacks of NAND strings of nonvolatile memory cells, a select line, and diodes.

The stacks of NAND strings of nonvolatile memory cells have two ends. One of the first end and the second end is coupled to bit lines and the other of the first end and the second end is coupled to source lines.

The select line is only at the first end of the NAND strings. The select line is not by the second end of the NAND strings. The select line electrically selectively couples the NAND strings to one of the bit lines and the source lines. The select line is arranged orthogonally over, and has surfaces conformal with, the stacks.

The diodes couple the strings of memory cells to the other of the bit lines and the source lines, such that the select line and the diodes are at opposite ends of the NAND strings.

One embodiment includes a plurality of word lines arranged orthogonally over, and having surfaces conformal with, the plurality of stacks. The word lines establish the nonvolatile memory cells at cross-points between surfaces of the plurality of stacks and the plurality of word lines. The select line is positioned between one of the bit lines and the source lines, and the plurality of word lines.

In one embodiment the source lines are electrically coupled to different horizontal plane positions of the stacks of NAND strings of nonvolatile memory cells.

In one embodiment the bit lines are electrically coupled to different ones of the stacks of NAND strings of nonvolatile memory cells.

In one embodiment the diodes are semiconductor p-n junctions.

In one embodiment the diodes are Schottky metal-semiconductor junctions.

In one embodiment the stacks of strings are parallel to the substrate.

In one embodiment the stacks of strings are perpendicular to the substrate.

In one embodiment the memory cells have interface regions between the stacks and word lines, the interface regions including a tunneling layer, a charge trapping layer and a blocking layer.

In one embodiment a first material of the source lines form first node of the diodes and a second material of the stacks of NAND strings form second nodes of the diodes.

Another aspect is a memory device, with an integrated circuit substrate and a 3D array of nonvolatile memory cells on the integrated circuit substrate.

The 3D array includes stacks of NAND strings of nonvolatile memory cells, select devices, and diodes.

The stacks of NAND strings of nonvolatile memory cells have two ends. One of the first end and the second end is coupled to bit lines and the other of the first end and the second end is coupled to source lines.

The select devices are only at the first end of the NAND strings. The select devices are not by the second end of the NAND strings. The select devices electrically selectively couple the NAND strings to one of the bit lines and the source lines.

The diodes couple the strings of memory cells to the other of the bit lines and the source lines, such that the select line and the diodes are at opposite ends of the NAND strings.

One embodiment further includes a plurality of word lines arranged orthogonally over, and having surfaces conformal with, the plurality of stacks. The word lines establish the nonvolatile memory cells at cross-points between surfaces of the plurality of stacks and the plurality of word lines. The select devices are positioned between one of the bit lines and the source lines, and the memory devices established by the plurality of word lines.

In one embodiment the source lines are electrically coupled to different horizontal plane positions of the stacks of NAND strings of nonvolatile memory cells.

In one embodiment the bit lines are electrically coupled to different ones of the stacks of NAND strings of nonvolatile memory cells.

In one embodiment the diodes are semiconductor p-n junctions.

In one embodiment the diodes are Schottky metal-semiconductor junctions.

In one embodiment the stacks of strings are parallel to the substrate.

In one embodiment the stacks of strings are perpendicular to the substrate.

In one embodiment the memory cells have interface regions between the stacks and word lines, the interface regions including a tunneling layer, a charge trapping layer and a blocking layer.

In one embodiment a first material of the source lines form first node of the diodes and a second material of the stacks of NAND strings form second nodes of the diodes.

Another aspect is a memory device, with an integrated circuit substrate and a 3D array of nonvolatile memory cells on the integrated circuit substrate.

The 3D array includes stacks of NAND strings of nonvolatile memory cells and diodes.

The stacks of NAND strings of nonvolatile memory cells have two ends. A first end is coupled to bit lines and a second end is coupled to source lines.

The diodes couple the strings of memory cells to the source lines. Only the diodes provide current flow control between the source lines and the second end of the stacks of NAND strings.

One embodiment further includes a plurality of word lines and select devices. The plurality of word lines is arranged orthogonally over, and having surfaces conformal with, the plurality of stacks. The word lines establish the nonvolatile memory cells at cross-points between surfaces of the plurality of stacks and the plurality of word lines.

The select devices are at the first end of the NAND strings by the bit lines. The select devices electrically selectively couple the NAND strings to the bit lines. The select devices are positioned between the bit lines and the memory devices established by the plurality of word lines.

In one embodiment the source lines are electrically coupled to different horizontal plane positions of the stacks of NAND strings of nonvolatile memory cells.

In one embodiment the bit lines are electrically coupled to different ones of the stacks of NAND strings of nonvolatile memory cells.

In one embodiment the diodes are semiconductor p-n junctions.

In one embodiment the diodes are Schottky metal-semiconductor junctions.

In one embodiment the stacks of strings are parallel to the substrate.

In one embodiment the stacks of strings are perpendicular to the substrate.

In one embodiment the memory cells have interface regions between the stacks and word lines, the interface regions including a tunneling layer, a charge trapping layer and a blocking layer.

In one embodiment a first material of the source lines form first node of the diodes and a second material of the stacks of NAND strings form second nodes of the diodes.

Another aspect is a method of operating a 3D NAND nonvolatile memory.

The method includes a step of applying a program bias arrangement sequence to NAND strings in the 3D NAND nonvolatile memory such that diodes are coupled between the NAND strings of memory cells and source lines. During programming, the diodes preserve a boosted channel of the NAND strings without relying on select devices between the NAND strings and the source lines.

The 3D memory device includes a plurality of ridge-shaped stacks, in the form of multiple strips of semiconductor material separated by insulating material, arranged in the examples described herein as strings which can be coupled through decoding circuits to sense amplifiers. The strips of semiconductor material have side surfaces on the sides of the ridge-shaped stacks. A plurality of conductive lines arranged in the examples, described herein as word lines which can be coupled to row decoders, extends orthogonally over the plurality of ridge-shaped stacks. The conductive lines have surfaces (e.g. bottom surfaces) that conform to the surface of the stacks. This conformal configuration results in a multi-layer array of interface regions at cross-points between side surfaces of the semiconductor material strips on the stacks and the conductive lines. Memory elements lie in the interface regions between the side surfaces of the strips and the conductive lines. The memory elements are programmable, like the programmable resistance structures or charge trapping structures in the embodiments described below. The combination of the conformal conductive line, the memory element and the semiconductor material strips within a stack at particular interface regions forms a stack of memory cells. As a result of the array structure, a 3D array of memory cells is provided.

The plurality of ridge-shaped stacks and the plurality of conductive lines can be made so that the memory cells are self-aligned. For example, the plurality of semiconductor material strips in the ridge-shaped stack can be defined using a single etch mask, resulting in formation of alternating trenches, which can be relatively deep, and stacks in which the side surfaces of the semiconductor material strips are vertically aligned or aligned on tapered sides of the ridges that result from the etch. The memory elements can be formed using a layer or layers of material made with blanket deposition processes over the plurality of stacks, and using other processes without a critical alignment step. Also, the plurality of conductive lines can be formed using a conformal deposition over the layer or layers of material used to provide the memory elements, followed by an etch process to define the lines using a single etch mask. As a result, a 3D array of self-aligned memory cells is established using only one alignment step for the semiconductor material strips in the plurality of stacks, and one alignment step for the plurality of conductive lines.

Also described herein is a 3D, buried-channel, junction-free NAND flash structure based on BE-SONOS technology.

This patent proposal provides a practical circuit design architecture for ultra high density 3D NAND Flash.

Other aspects and advantages of the present invention can be seen on review of the drawings, the detailed description and the claims, which follow.

### BRIEF DESCRIPTION OF THE DRAWINGS

FIG. 1 is a perspective illustration of a 3D memory structure as described herein including a plurality of planes of semiconductor material strips parallel to a Y-axis, arranged in a plurality of ridge-shaped stacks, a memory layer on side surfaces of the semiconductor material strips, and a plurality of conductive lines with conformal bottom surfaces arranged over the plurality of ridge-shaped stacks.

FIG. 2 is a cross-section of a memory cell taken in the X-Z plane from the structure of FIG. 1.

FIG. 3 is a cross-section of a memory cell taken in the X-Y plane from the structure of FIG. 1.

FIG. 4 is a schematic diagram of an anti-fuse based memory having the structure of FIG. 1.

FIG. 5 is a perspective illustration of a 3D NAND-flash memory structure as described herein including a plurality of planes of semiconductor material strips parallel to a Y-axis, arranged in a plurality of ridge-shaped stacks, a charge trapping memory layer on side surfaces of the semiconductor material strips, and a plurality of conductive lines with conformal bottom surfaces arranged over the plurality of ridge-shaped stacks.

FIG. 6 is a cross-section of a memory cell taken in the X-Z plane from the structure of FIG. 5.

FIG. 7 is a cross-section of a memory cell taken in the X-Y plane from the structure of FIG. 5.

FIG. 8 is a schematic diagram of NAND flash memory having the structure of FIG. 5 and FIG. 23.

FIG. 9 is a perspective illustration of an alternative implementation of a 3D NAND-flash memory structure like that of FIG. 5, where the memory layer is removed between the conductive lines.

FIG. 10 is a cross-section of a memory cell taken in the X-Z plane from the structure of FIG. 9.

FIG. 11 is a cross-section of a memory cell taken in the X-Y plane from the structure of FIG. 9.

FIG. 12 illustrates a first stage in a process for manufacturing a memory device like that of FIGS. 1, 5 and 9.

FIG. 13 illustrates a second stage in a process for manufacturing a memory device like that of FIGS. 1, 5 and 9.

FIG. 14A illustrates a third stage in a process for manufacturing a memory device like that of FIG. 1.

FIG. 14B illustrates a third stage in a process for manufacturing a memory device like that of FIG. 5.

FIG. 15 illustrates a third stage in a process for manufacturing a memory device like that of FIGS. 1, 5 and 9.

FIG. 16 illustrates a fourth stage in a process for manufacturing a memory device like that of FIGS. 1, 5 and 9.

FIG. 17 is a schematic diagram of an integrated circuit including a 3D programmable resistance memory array with row, column and plane decoding circuitry.

FIG. 18 is a schematic diagram of an integrated circuit including a 3D NAND-flash memory array with row, column and plane decoding circuitry.

FIG. 19 is a transmission electron microscope TEM image of a portion of 3D NAND-flash memory array.

FIG. 20 is a perspective view of a 3D NAND-flash memory structure including diodes in the strings between the source line structures and the memory strings.

FIG. 21 is a perspective schematic diagram of a 3D NAND-flash memory structure including diodes in the strings between the source line structures and the memory strings, showing 2 planes of memory cells each having 8 charge trapping cells arranged in a NAND configuration.

FIG. 22 is a timing diagram for a programming operation in an array like that of FIG. 21 including diodes in the strings between the source line structures and the memory strings.

FIG. 23 is a perspective view of a 3D NAND-flash memory structure including diodes in the strings between the source line structures and the memory strings, undergoing a read operation.

FIG. 24 is a perspective view of a 3D NAND-flash memory structure including diodes in the strings between the source line structures and the memory strings, undergoing a program operation.

FIG. 25 is a perspective view of a 3D NAND-flash memory structure including

Schottky diodes in the strings between the source line structures and the memory strings.

FIG. 26 is a perspective view of a vertical channel version of a 3D NAND-flash memory structure including diodes in the strings between the source line structures and the memory strings.

FIGS. 27A and 27B are transmission electron microscope TEM images of a portion of 3D NAND-flash memory array.

FIG. 28 is a graph of IV characteristics of experimentally measured PN diodes.

FIG. 29 is a graph of the program inhibit characteristics of experimentally measured polysilicon diode connected 3D NAND memory.

FIG. 30 is a graph of threshold voltage distribution for experimentally measured polysilicon diode connected 3D NAND memory having a checkerboard distribution of programmed/erased memory cells.

FIG. 31 is a layout view of a 3D NAND-flash memory array structure including diodes in the strings between the source line structures and the memory strings.

FIG. 32 is another layout view of a 3D NAND-flash memory array structure including diodes in the strings between the source line structures and the memory strings.

FIG. 33 is yet another layout view of a 3D NAND-flash memory array structure including diodes in the strings between the source line structures and the memory strings.

FIG. 34 is a perspective view of a 3D NAND-flash memory structure including diodes in the strings between the source line structures and the memory strings.

FIG. 35 is a perspective view of a 3D NAND-flash memory structure including diodes in the strings between the source line structures and the memory strings.

### DETAILED DESCRIPTION

A detailed description of embodiments is provided with reference to the Figures.

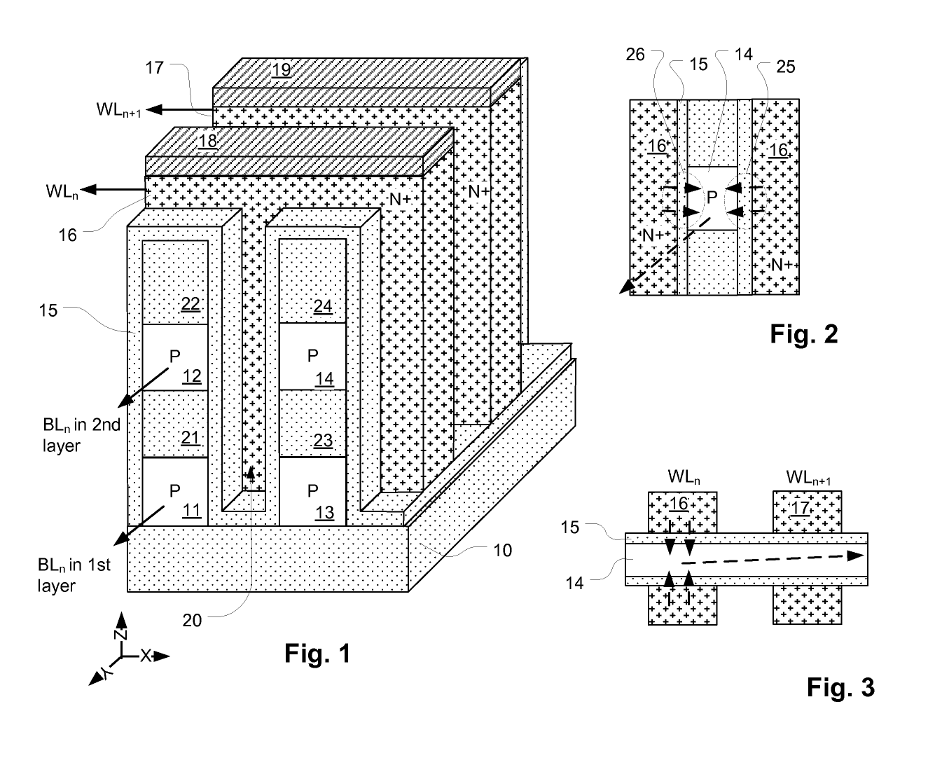

FIG. 1 is a perspective drawing of a 2×2 portion of a three-dimensional programmable resistance memory array with fill material removed from the drawing to give a view of the stacks of semiconductor material strips and orthogonal conductive lines that make up the 3D array. In this illustration, only 2 planes are shown. However, the number of planes can be extended to very large numbers. As shown in FIG. 1, the memory array is formed on an integrated circuit substrate having an insulating layer 10 over underlying semiconductor or other structures (not shown). The memory array includes a plurality of stacks of semiconductor material strips 11, 12, 13, 14 separated by insulating material 21, 22, 23, 24. The stacks are ridge-shaped extending on the Y-axis as illustrated in the figure, so that the semiconductor material strips 11-14 can be configured as strings. Semiconductor material strips 11 and 13 can act as strings in a first memory plane. Semiconductor material strips 12 and 14 can act as strings in a second memory plane. A layer 15 of memory material, such as an anti-fuse material, coats the plurality of stacks of semiconductor material strips in this example, and at least on the side walls of the semiconductor material strips in other examples. A plurality of conductive lines 16, 17 is arranged orthogonally over the plurality of stacks of semiconductor material strips. The conductive lines 16, 17 have surfaces conformal with the plurality of stacks of semiconductor material strips, filling the trenches (e.g. 20) defined by the plurality of stacks, and defining a multi-layer array of interface regions at cross-points between side surfaces of the semiconductor material strips 11-14 on the stacks and conductive lines 16, 17. A layer of silicide (e.g. tungsten silicide, cobalt silicide, titanium silicide) 18, 19 can be formed over the top surfaces of the conductive lines 16, 17.

The layer 15 of memory material can consist of an anti-fuse material such as a silicon dioxide, silicon oxynitride or other silicon oxide, for example having a thickness on the order of 1 to 5 nanometers. Other anti-fuse materials may be used, such as silicon nitride. The semiconductor material strips 11-14 can be a semiconductor material with a first conductivity type (e.g. p-type). The conductive lines 16, 17 can be a semiconductor material with a second conductivity type (e.g. n-type). For example, the semiconductor material strips 11-14 can be made using p-type polysilicon while the conductive lines 16, 17 can be made using relatively heavily doped n+-type polysilicon. The width of the semiconductor material strips should be enough to provide room for a depletion region to support the diode operation. As result, memory cells comprising a rectifier formed by the p-n junction with a programmable anti-fuse layer in between the anode and cathode are formed in the 3D array of cross-points between the polysilicon strips and lines. In other embodiments, different programmable resistance memory materials can be used, including transition metal oxides like tungsten oxide on tungsten or doped metal oxide conductive strips. Such materials can be programmed and erased, and can be implemented for operations storing multiple bits per cell.

FIG. 2 shows a cross-section view cut in the X-Z plane of the memory cell formed at the intersection of conductive line 16 and semiconductor material strip 14. Active regions 25, 26 are formed on the both sides of the strip 14 between the conductive line 16 and the semiconductor material strip 14. In the native state, a layer 15 of anti-fuse material has a high resistance. After programming, the anti-fuse material breaks down, causing one or both of the active areas 25, 26 within the anti-fuse material to assume a low resistance state. In the embodiment described here, each memory cell has two active regions 25, 26, one on each side of the semiconductor material strip 14. FIG. 3 shows a cross-section view in the X-Y plane of the memory cell formed at the intersection of the conductive lines 16, 17 and the semiconductor material strip 14. The current path from the word line defined by the conductive line 16 through the layer 15 of anti-fuse material and down the semiconductor material strip 14 is illustrated.

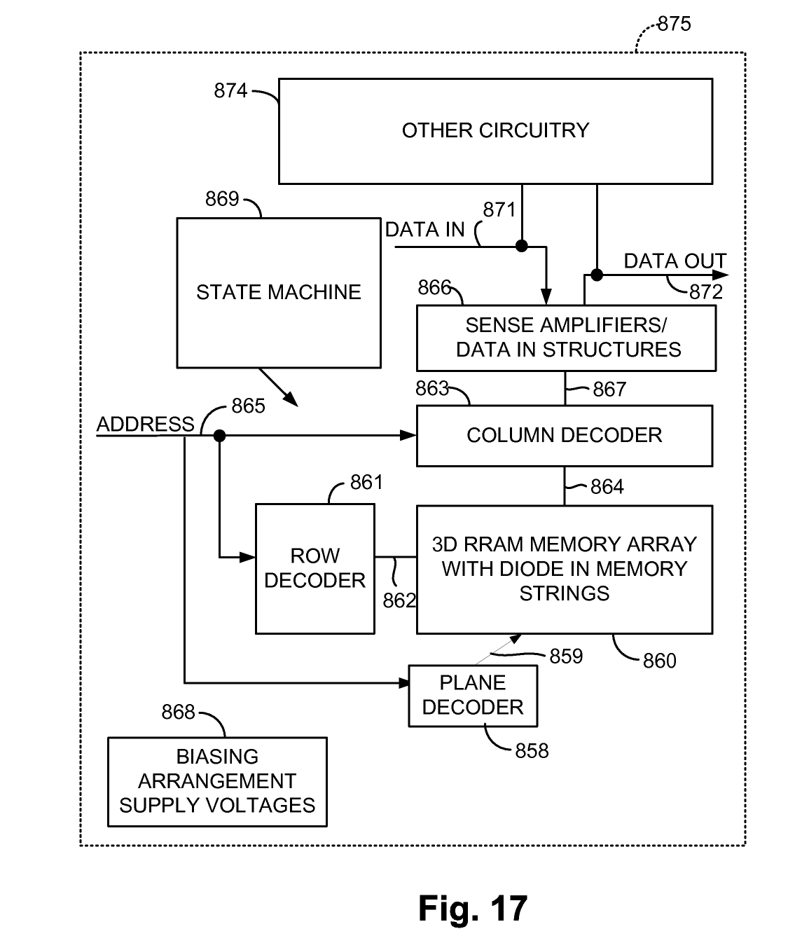

Electron current as illustrated by the dashed arrows in FIG. 3, flows from the n+ conductive lines 16 into the p-type semiconductor material strips, and along the semiconductor material strip (—arrow) to sense amplifiers where it can be measured to indicate the state of a selected memory cell. In a typical embodiment, using a layer of silicon oxide about one nanometer thick as the anti-fuse material, a programming pulse may comprise a 5 to 7 volt pulse having a pulse width of about one microsecond, applied under control of on-chip control circuits as described below with reference to FIG. 17. A read pulse may comprise a 1 to 2 volt pulse having a pulse width that depends on the configuration, applied under control of on-chip control circuits as described below with reference to FIG. 17. The read pulse can be much shorter than the programming pulse.

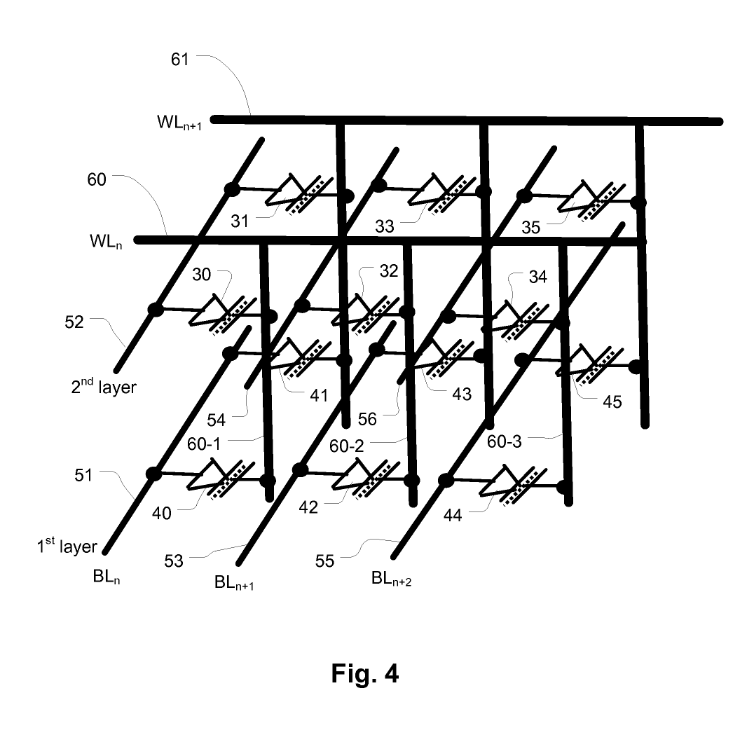

FIG. 4 is a schematic diagram showing 2 planes of memory cells having 6 cells each. The memory cells are represented by diode symbols with a dashed line representing the layer of anti-fuse material between the anode and the cathode. The 2 planes of memory cells are defined at the cross-points of conductive lines 60, 61 acting as a first word line WLn and a second word line WLn+1 with a first stack of semiconductor material strips 51, 52, a second stack of semiconductor material strips 53, 54 and a third stack of semiconductor material strips 55, 56 acting as strings BLn, BLn+1 and BLn+2 in first and second layers of the array. The first plane of memory cells includes memory cells 30, 31 on semiconductor material strip 52, memory cells 32, 33 on semiconductor material strip 54, and memory cells 34, 35 on semiconductor material strip 56. The second plane of memory cells includes memory cells 40, 41 on semiconductor material strip 51, memory cells 42, 43 on semiconductor material strip 53, and memory cells 44, 45 on semiconductor material strip 55. As shown in the figure, the conductive line 60, acting as word line WLn, includes vertical extensions 60-1, 60-2, 60-3 which correspond with the material in the trench 20 shown in FIG. 1 between the stacks in order to couple the conductive line 60 to the memory cells along the 3 illustrated semiconductor material strips in each plane. An array having many layers can be implemented as described herein, enabling very high density memory approaching or reaching terabits per chip.

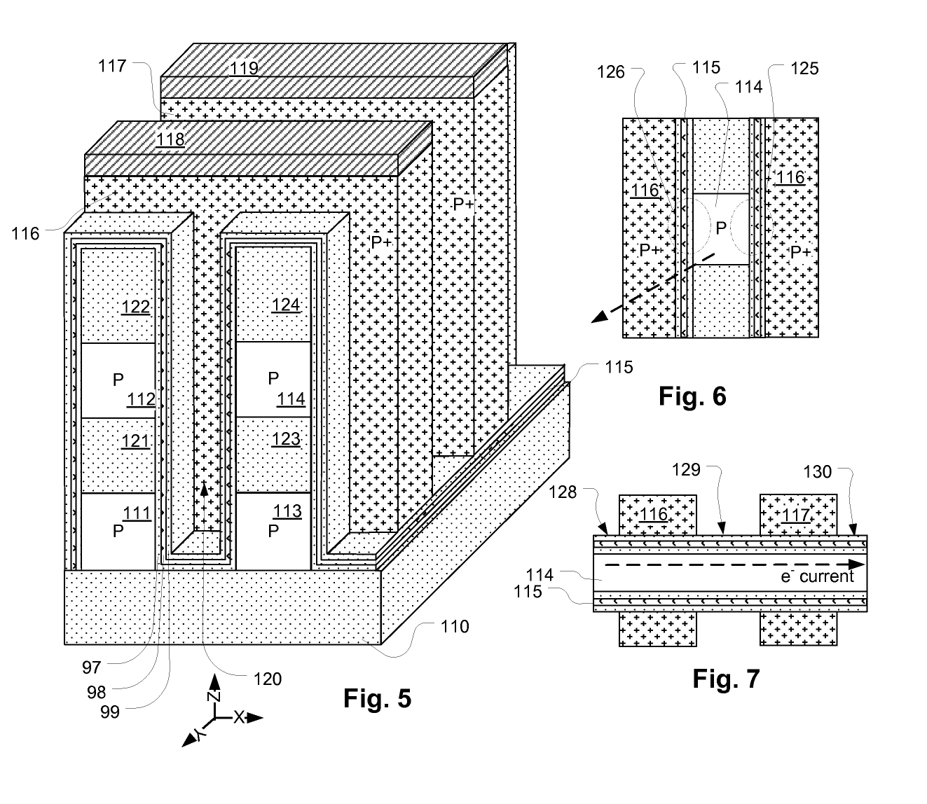

FIG. 5 is a perspective drawing of a 2×2 portion of a three-dimensional charge trapping memory array with fill material removed from the drawing to give a view of the stacks of semiconductor material strips and orthogonal conductive lines that make up the 3D array. In this illustration, only 2 layers are shown. However, the number of layers can be extended to very large numbers. As shown in FIG. 5, the memory array is formed on an integrated circuit substrate having an insulating layer 110 over underlying semiconductor or other structures (not shown). The memory array includes a plurality of stacks (2 are shown in the drawing) of semiconductor material strips 111, 112, 113, 114 separated by insulating material 121, 122, 123, 124. The stacks are ridge-shaped extending on Y-axis as illustrated in the figure, so that the semiconductor material strips 111-114 can be configured as strings. Semiconductor material strips 111 and 113 can act as strings in a first memory plane. Semiconductor material strips 112 and 114 can act as strings in a second memory plane.

The insulating material 121 between the semiconductor material strips 111 and 112 in a first stack and the insulating material 123 between semiconductor material strips 113 and 114 in the second stack has an effective oxide thickness of about 40 nm or greater, where effective oxide thickness EOT is a thickness of the insulating material normalized according to a ratio of the dielectric constant of silicon dioxide and the dielectric constant of the chosen insulation material. The term “about 40 nm” is used here to account for variations on the order of 10% or so, as arise typically in manufacturing structures of this type. The thickness of the insulating material can play a critical role in reducing interference between cells in adjacent layers of the structure. In some embodiments, the EOT of the insulating material can be as small as 30 nm while achieving sufficient isolation between the layers.

A layer 115 of memory material, such as a dielectric charge trapping structure, coats the plurality of stacks of semiconductor material strips in this example. A plurality of conductive lines 116, 117 is arranged orthogonally over the plurality of stacks of semiconductor material strips. The conductive lines 116, 117 have surfaces conformal with the plurality of stacks of semiconductor material strips, filling the trenches (e.g. 120) defined by the plurality of stacks, and defining a multi-layer array of interface regions at cross-points between side surfaces of the semiconductor material strips 111-114 on the stacks and conductive lines 116, 117. A layer of silicide (e.g. tungsten silicide, cobalt silicide, titanium silicide) 118, 119 can be formed over the top surfaces of the conductive lines 116, 117.

Nanowire MOSFET type cells can also be configured in this manner, by providing nanowire or nanotube structures in channel regions on conductive lines 111-114, like those described in Paul, et al., “Impact of a Process Variation on Nanowire and Nanotube Device Performance”, IEEE Transactions on Electron Devices, Vol. 54, No. 9, September 2007, which article is incorporated by reference as if fully set forth herein.

As a result, a 3D array of SONOS-type memory cells configured in a NAND flash array can formed. The source, drain and channel are formed in the silicon (S) semiconductor material strips 111-114, the layer 115 of the memory material includes a tunneling dielectric layer 97 which can be formed of silicon oxide (O), a charge storage layer 98 which can be formed of silicon nitride (N), a blocking dielectric layer 99 which can be formed of silicon oxide (O), and the gate comprises polysilicon (S) of the conductive lines 116, 117.

The semiconductor material strips 111-114 can be a p-type semiconductor material. The conductive lines 116, 117 can be a semiconductor material with the same or a different conductivity type (e.g. p+-type). For example, the semiconductor material strips 111-114 can be made using p-type polysilicon, or p-type epitaxial single crystal silicon, while the conductive lines 116, 117 can be made using relatively heavily doped p+-type polysilicon.

Alternatively, the semiconductor material strips 111-114 can be n-type semiconductor material. The conductive lines 116, 117 can be a semiconductor material with the same or a different conductivity type (e.g. p+-type). This n-type strip arrangement results in buried-channel, depletion mode charge trapping memory cells. For example, the semiconductor material strips 111-114 can be made using n-type polysilicon, or n-type epitaxial single crystal silicon, while the conductive lines 116, 117 can be made using relatively heavily doped p+-type polysilicon. A typical doping concentration for n-type semiconductor material strips can be around 10¹⁸/cm³, with usable embodiments likely in the range of 10¹⁷/cm³ to 10¹⁹/cm³. The use of n-type semiconductor material strips can be particularly beneficial in junction-free embodiments to improve conductivity along the NAND strings and thereby allowing higher read current.

Thus, memory cells comprising field effect transistors having charge storage structures are formed in the 3D array of cross-points. Using dimensions for the widths of the semiconductor material strips and conductive lines on the order of 25 nanometers, with gaps between the ridge-shaped stacks on the order of 25 nanometers, a device having a few tens of layers (e.g. 30 layers) can approach terabit capacity (10¹²) in a single chip.

The layer 115 of memory material can comprise other charge storage structures. For example, a bandgap engineered SONOS (BE-SONOS) charge storage structure can be used which includes a dielectric tunneling layer 97 that includes a composite of materials forming an inverted “U” shaped valence band under zero bias. In one embodiment, the composite tunneling dielectric layer includes a first layer referred to as a hole tunneling layer, a second layer referred to as a band offset layer, and a third layer referred to as an isolation layer. The hole tunneling layer of the layer 115 in this embodiment comprises silicon dioxide on the side surface of the semiconductor material strips formed for example using in-situ steam generation ISSG with optional nitridation by either a post deposition NO anneal or by addition of NO to the ambient during deposition. The thickness of the first layer of silicon dioxide is less than 20 Å, and preferably 15 Å or less. Representative embodiments can be 10 Å or 12 Å thick.

The band offset layer in this embodiment comprises silicon nitride lying on the hole tunneling layer, formed for example using low-pressure chemical vapor deposition LPCVD, using for example dichlorosilane DCS and NH₃ precursors at 680° C.

In alternative processes, the band offset layer comprises silicon oxynitride, made using a similar process with an N₂O precursor. The band offset layer thickness of silicon nitride is less than 30 Å, and preferably 25 Å or less.

The isolation layer in this embodiment comprises silicon dioxide, lying on the band offset layer of silicon nitride formed for example using LPCVD high temperature oxide HTO deposition. The thickness of the isolation layer of silicon dioxide is less than 35 Å, and preferably 25 Å or less. This three-layer tunneling layer results in an inverted U-shaped valence band energy level.

The valence band energy level at the first location is such that an electric field sufficient to induce hole tunneling through the thin region between the interface with the semiconductor body and the first location, is also sufficient to raise the valence band energy level after the first location to a level that effectively eliminates the hole tunneling barrier in the composite tunneling dielectric after the first location. This structure establishes an inverted U-shaped valence band energy level in the three-layer tunneling dielectric layer, and enables electric field assisted hole tunneling at high speeds while effectively preventing charge leakage through the composite tunneling dielectric in the absence of electric fields or in the presence of smaller electric fields induced for the purpose of other operations, such as reading data from the cell or programming adjacent cells.

In a representative device, the layer 115 of memory material includes a bandgap engineered composite tunneling dielectric layer comprising a layer of silicon dioxide less than 2 nm thick, a layer of silicon nitride less than 3 nm thick, and a layer of silicon dioxide less that 4 nm thick. In one embodiment, the composite tunneling dielectric layer consists of an ultrathin silicon oxide layer O1 (e.g. <=15 Å), an ultrathin silicon nitride layer N1 (e.g. <=30 Å) and an ultrathin silicon oxide layer O2 (e.g. <=35 Å), which results in an increase in the valence band energy level of about 2.6 eV at an offset 15 Å or less from the interface with the semiconductor body. The O2 layer separates the N1 layer from the charge trapping layer, at a second offset (e.g. about 30 Å to 45 Å from the interface), by a region of lower valence band energy level (higher hole tunneling barrier) and higher conduction band energy level. The electric field sufficient to induce hole tunneling raises the valence band energy level after the second location to a level that effectively eliminates the hole tunneling barrier, because the second location is at a greater distance from the interface. Therefore, the O2 layer does not significantly interfere with the electric field assisted hole tunneling, while improving the ability of the engineered tunneling dielectric to block leakage during low fields.

A charge trapping layer in the layer 115 of memory material in this embodiment comprises silicon nitride having a thickness greater than 50 Å, including for example about 70 Å in this embodiment formed for example using LPCVD. Other charge trapping materials and structures may be employed, including for example silicon oxynitride (SiₓO_{y}N_{z}), silicon-rich nitride, silicon-rich oxide, trapping layers including embedded nano-particles and so on.

The blocking dielectric layer in the layer 115 of memory material in this embodiment comprises a layer of silicon dioxide having a thickness greater than 50 Å, including for example about 90 Å in this embodiment, can be formed by wet conversion from the nitride by a wet furnace oxidation process. Other embodiments may be implemented using high temperature oxide (HTO) or LPCVD SiO₂. Other blocking dielectrics can include high-K materials like aluminum oxide.

In a representative embodiment, the hole tunneling layer can be 13 Å of silicon dioxide; the band offset layer can be 20 Å of silicon nitride; the isolation layer can be 25 Å of silicon dioxide; the charge trapping layer can be 70 Å of silicon nitride; and the blocking dielectric layer can be silicon oxide 90 Å thick. The gate material is the p+ polysilicon (work function about 5.1 eV) used in the conductive lines 116, 117.

FIG. 6 shows a cross-section view cut in the X-Z plane of the charge trapping memory cell formed at the intersection of conductive line 116 and semiconductor material strip 114. Active charge trapping regions 125, 126 are formed on the both sides of the strip 114 between the conductive lines 116 and the strip 114. In the embodiment described here, as shown in FIG. 6, each memory cell is a double gate field effect transistor having active charge storage regions 125, 126, one on each side of the semiconductor material strip 114.

FIG. 7 shows a cross-section view cut in the X-Y plane of the charge trapping memory cell formed at the intersection of the conductive lines and 116, 117 and the semiconductor material strip 114. The current path down the semiconductor material strip 114 is illustrated. Electron current as illustrated by the dashed arrows in the diagram flows along the p-type semiconductor material strips, to sense amplifiers where it can be measured to indicate the state of a selected memory cell. The source/drain regions 128, 129, 130 between the conductive lines 116, 117 which act as word lines can be “junction-free”, without source and drain doping having a conductivity type opposite that of the channel regions beneath the word lines. In the junction free embodiment, the charge trapping field effect transistors can have a p-type channel structure. Also, source and drain doping could be implemented in some embodiments, in a self-aligned implant after word line definition.

In alternative embodiments, the semiconductor material strips 111-114 can be implemented using a lightly doped n-type semiconductor body in junction free arrangements, resulting in a buried-channel field effect transistor which can operate in depletion mode, with naturally shifted lower threshold distributions for the charge trapping cells.

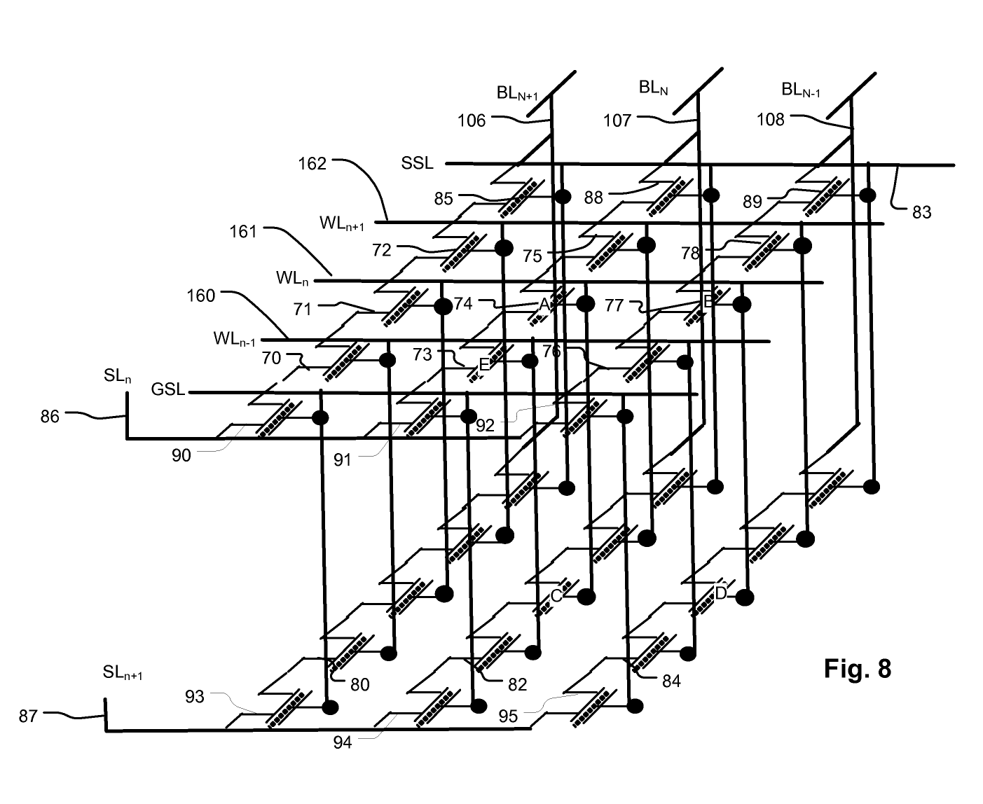

FIG. 8 is a schematic diagram showing 2 planes of memory cells having 9 charge trapping cells arranged in a NAND configuration, which is representative of a cube which can include many planes and many word lines. The 2 planes of memory cells are defined at the cross-points of conductive lines 160, 161, 162 acting as a word line WLn−1, word line WLn, and word line WLn+1, with a first stack of semiconductor material strips, a second stack of semiconductor material strips and a third stack of semiconductor material strips.

The first plane of memory cells includes memory cells 70, 71, 72 in a NAND string on a semiconductor material strip, memory cells 73, 74, 75 in a NAND string on a semiconductor material strip, and memory cells 76, 77, 78 in a NAND string on a semiconductor material strip. The second plane of memory cells corresponds with a bottom plane in the cube in this example, and includes memory cells (e.g. 80, 82, 84) arranged in NAND strings in a similar manner those in the first plane.

As shown in the figure, the conductive line 161 acting as word line WLn includes vertical extensions which correspond with the material in the trench 120 shown in FIG. 5 between the stacks, in order to couple the conductive line 161 to the memory cells (cells 71, 74, 77 in the first plane) in the interface regions in the trenches between the semiconductor material strips in all of the planes.

The bit lines and source lines are at opposite ends of the memory strings. Bit lines 106, 107 and 108, are connected to different stacks of memory strings and are controlled by bit line signals BLₙ₋₁, BLₙ and BLₙ₊₁. Source line 86 controlled by signal SSLₙ terminates NAND strings in the upper plane in this arrangement. Likewise, source line 87 controlled by signal SSLₙ₊₁ terminates NAND strings in the lower plane in this arrangement.

String select transistors 85, 88, and 89 are connected between the NAND strings and a respective one of the bit lines BL_{N+1}, BL_{N}, BL_{N+1} in this arrangement. String select lines 83 is parallel to the word lines.

Block select transistors 90-95 couple the NAND strings to one of the source lines. The ground select line signal GSL in this example is coupled to the gates of the block select transistors 90-95, and can be implemented in the same manner as the conductive lines 160, 161 and 162. The string select transistors and block select transistors can use the same dielectric stack as a gate oxide as the memory cells in some embodiments. In other embodiments, a typical gate oxide is used instead. Also, the channel lengths and widths can be adjusted as suits the designer to provide the switching function for the transistors.

Other embodiments shown below remove the GSL ground select line and the select transistors 90-95 controlled by the ground select line; such embodiments rely on a diode between the source line and the memory cells to control charge flow at the source line end of the memory strings.

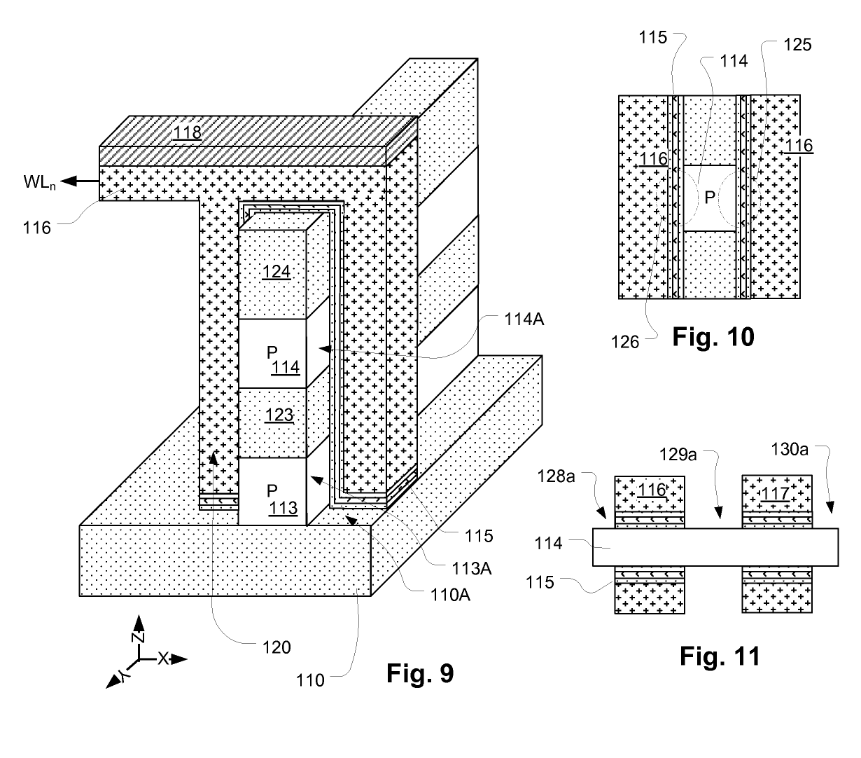

FIG. 9 is a perspective drawing of an alternative structure like that of FIG. 5. The reference numerals of similar structures are reused in the figure, and not described again. FIG. 9 differs from FIG. 5 in that the surface 110A of the insulating layer 110, and the side surfaces 113A, 114A of the semiconductor material strips 113, 114 are exposed between the conductive lines 116 which act as word lines, as a result of the etch process which forms the word lines. Thus, the layer 115 of memory material can be completely or partially etched between the word lines without harming operation. However, there is no necessity in some structures for etching through the memory layer 115 forming the dielectric charge trapping structures like those described here.

FIG. 10 is a cross-section of a memory cell in the X-Z plane like that of FIG. 6. FIG. 10 is identical to FIG. 6, illustrating that a structure like that of FIG. 9 results in memory cells that are the same as those implemented in the structure of FIG. 5 in this cross-section. FIG. 11 is a cross-section section of a memory cell in the X-Y plane like that of FIG. 7. FIG. 11 differs from FIG. 7 in that the regions 128a, 129a and 130a along the side surfaces (e.g. 114A) of the semiconductor material strip 114 may have the memory material removed.

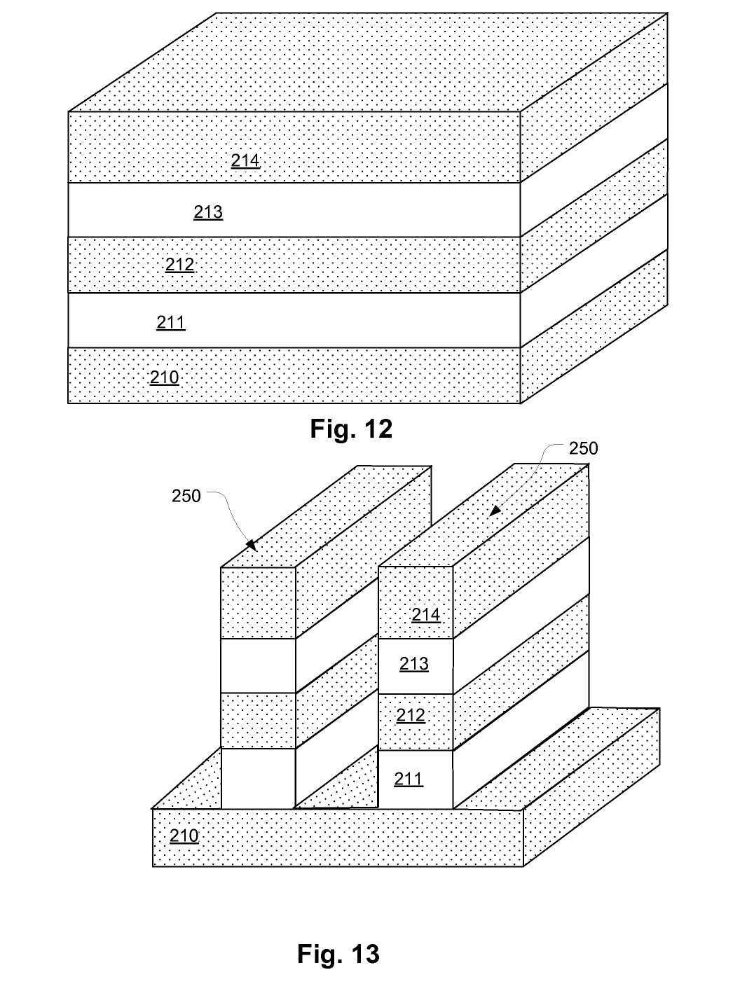

FIGS. 12-16 illustrate stages in a basic process flow for implementing 3D memory arrays as described above utilizing only 2 pattern masking steps that are critical alignment steps for array formation. In FIG. 12, a structure is shown which results from alternating deposition of insulating layers 210, 212, 214 and conductor layers 211, 213 formed using doped semiconductors for example in a blanket deposition in the array area of a chip. Depending on the implementation, the conductor layers 211, 213 can be implemented using polysilicon or epitaxial single crystal silicon having n-type or p-type doping. Inter-level insulating layers 210, 212, 214 can be implemented for example using silicon dioxide, other silicon oxides, or silicon nitride. These layers can be formed in a variety of ways, including low pressure chemical vapor deposition LPCVD processes available in the art.

FIG. 13 shows the result of a first lithographic patterning step used to define a plurality of ridge-shaped stacks 250 of semiconductor material strips, where the semiconductor material strips are implemented using the material of the conductor layers 211, 213, and separated by the insulating layers 212, 214. Deep, high aspect ratio trenches can be formed in the stack, supporting many layers, using lithography based processes applying a carbon hard mask and reactive ion etching.

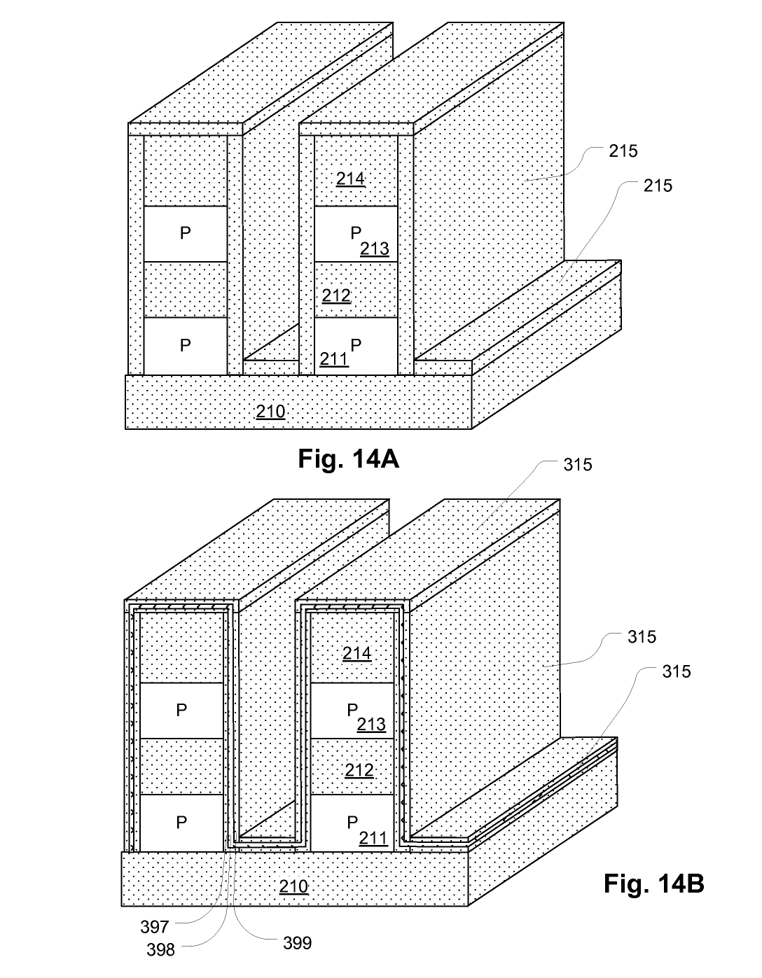

FIGS. 14A and 14B show the next stage for, respectively, an embodiment including a programmable resistance memory structure such as an anti-fuse cell structure, and an embodiment including a programmable charge trapping memory structure such as a SONOS type memory cell structure.

FIG. 14A shows results of a blanket deposition of a layer 215 of memory material in an embodiment in which the memory material consists of a single layer as in the case of an anti-fuse structure like that shown in FIG. 1. In an alternative, rather than a blanket deposition, an oxidation process can be applied to form oxides on the exposed sides of the semiconductor material strips, where the oxides act as the memory material.

FIG. 14B shows results of blanket deposition of a layer 315 that comprises multilayer charge trapping structure including a tunneling layer 397, a charge trapping layer 398 and a blocking layer 399 as described above in connection with FIG. 4. As shown in FIGS. 14A and 14B, the memory layers 215, 315 are deposited in a conformal manner over the ridge-shaped stacks (250 of FIG. 13) of semiconductor material strips.

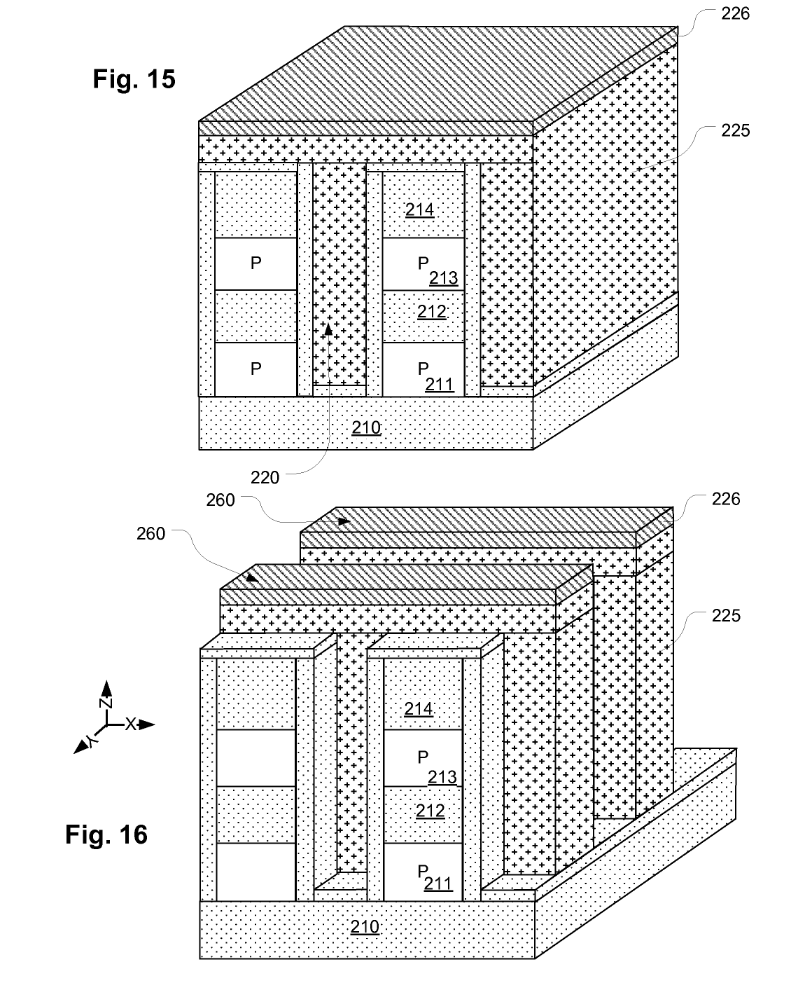

FIG. 15 shows the results of a high aspect ratio fill step in which conductive material, such as polysilicon having n-type or p-type doping, to be used for the conductive lines which act as word lines, is deposited to form layer 225. Also, a layer of silicide 226 can be formed over the layer 225 in embodiments in which polysilicon is utilized. As illustrated in the figure, high aspect ratio deposition technologies such as low-pressure chemical vapor deposition of polysilicon in the illustrated embodiments is utilized to completely fill the trenches 220 between the ridge-shaped stacks, even very narrow trenches on the order of 10 nanometers wide with high aspect ratio.

FIG. 16 shows results of the second lithographic patterning step used to define a plurality of conductive lines 260 which act as word lines for the 3D memory array. The second lithographic patterning step utilizes a single mask for critical dimensions of the array for etching high aspect ratio trenches between the conductive lines, without etching through the ridge-shaped stacks. Polysilicon can be etched using an etch process that is highly selective for polysilicon over silicon oxides or silicon nitrides. Thus, alternating etch processes are used, relying on the same mask to etch through the conductor and insulating layers, with the process stopping on the underlying insulating layer 210.

An optional manufacturing step includes forming hard masks over the plurality of conductive lines, including word lines, ground select lines, and string select lines. The hard masks can be formed using a relatively thick layer of silicon nitride or other material which can block ion implantation processes. After the hard masks are formed, an implant can be applied to increase the doping concentration in the semiconductor material strips, and thereby reduce the resistance of the current path along the semiconductor material strips. By utilizing controlled implant energies, the implants can be caused to penetrate to the bottom semiconductor material strip, and each overlying semiconductor material strip in the stacks.

The hard masks are removed, exposing the silicide layers along the top surfaces of the conductive lines. After an interlayer dielectric is formed over the top of the array, vias are opened in which contact plugs using tungsten fill for example, are formed. Overlying metal lines are patterned to connect as BL lines, to decoder circuits. A three-plane decoding network is established in the illustrated manner, accessing a selected cell using one word line, one bit line and one source line. See, U.S. Pat. No. 6,906,940, entitled Plane Decoding Method and Device for Three Dimensional Memories.

To program a selected anti-fuse type cell, in this embodiment the selected word line can be biased with −7 Volts, the unselected word lines can be set at 0 Volts, the selected bit line can be set at 0 Volts, the unselected bit lines can be set at 0 Volts, the selected SL line can be set at −3.3 volts, and the unselected SL lines can be set at 0 Volts. To read a selected cell, in this embodiment the selected word line can be biased with −1.5 Volts, the unselected word lines can be set at 0 Volts, the selected bit line can be set at 0 Volts, the unselected bit lines can be set at 0 Volts, the selected SL line can be set at −3.3 volts, and the unselected SL lines can be set at 0 Volts.

FIG. 17 is a simplified block diagram of an integrated circuit according to an embodiment of the present invention. The integrated circuit line 875 includes a 3D programmable resistance memory array 860 (RRAM) implemented as described herein, on a semiconductor substrate. A row decoder 861 is coupled to a plurality of word lines 862, and arranged along rows in the memory array 860. A column decoder 863 is coupled to a plurality of bit lines 864 arranged along columns in the memory array 860 for reading and programming data from the memory cells in the array 860. A plane decoder 858 is coupled to a plurality of planes in the memory array 860 on source lines 859. Addresses are supplied on bus 865 to column decoder 863, row decoder 861 and plane decoder 858. Sense amplifiers and data-in structures in block 866 are coupled to the column decoder 863 in this example via data bus 867. Data is supplied via the data-in line 871 from input/output ports on the integrated circuit 875 or from other data sources internal or external to the integrated circuit 875, to the data-in structures in block 866. In the illustrated embodiment, other circuitry 874 is included on the integrated circuit, such as a general purpose processor or special purpose application circuitry, or a combination of modules providing system-on-a-chip functionality supported by the programmable resistance cell array. Data is supplied via the data-out line 872 from the sense amplifiers in block 866 to input/output ports on the integrated circuit 875, or to other data destinations internal or external to the integrated circuit 875.

A controller implemented in this example using bias arrangement state machine 869 controls the application of bias arrangement supply voltage generated or provided through the voltage supply or supplies in block 868, such as read and program voltages. The controller can be implemented using special-purpose logic circuitry as known in the art. In alternative embodiments, the controller comprises a general-purpose processor, which may be implemented on the same integrated circuit, which executes a computer program to control the operations of the device. In yet other embodiments, a combination of special-purpose logic circuitry and a general-purpose processor may be utilized for implementation of the controller.

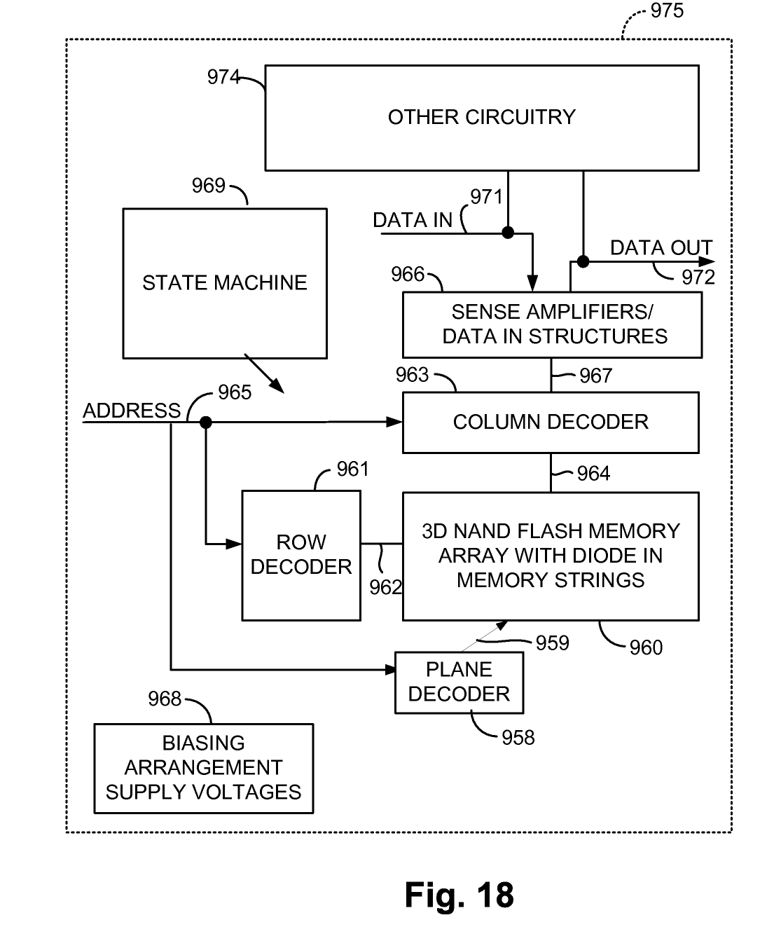

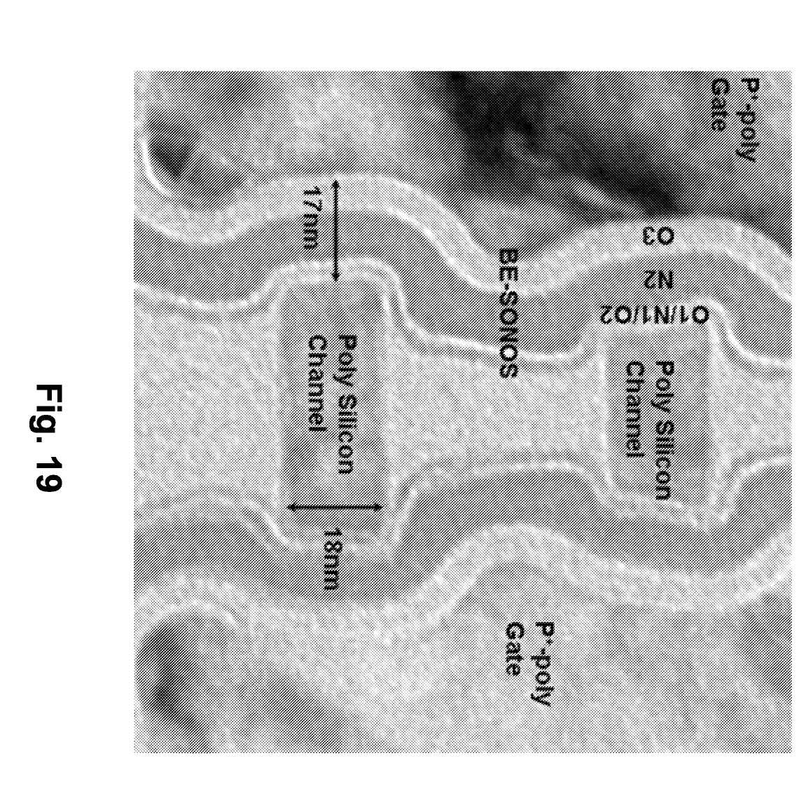

FIG. 18 is a simplified block diagram of an integrated circuit according to an embodiment of the present invention. The integrated circuit line 975 includes a 3D NAND flash memory array 960, implemented as described herein including diodes in the memory strings, on a semiconductor substrate. A row decoder 961 is coupled to a plurality of word lines 962, and arranged along rows in the memory array 960. A column decoder 963 is coupled to a plurality of bit lines 964 arranged along columns in the memory array 960 for reading and programming data from the memory cells in the array 960. A plane decoder 958 is coupled to a plurality of planes in the memory array 960 via source lines 959. Addresses are supplied on bus 965 to column decoder 963 including a page buffer, row decoder 961 and plane decoder 958. Sense amplifiers and data-in structures in block 966 are coupled to the column decoder 963 in this example via data bus 967. Data is supplied via the data-in line 971 from input/output ports on the integrated circuit 975 or from other data sources internal or external to the integrated circuit 975, to the data-in structures in block 966. In the illustrated embodiment, other circuitry 974 is included on the integrated circuit, such as a general purpose processor or special purpose application circuitry, or a combination of modules providing system-on-a-chip functionality supported by the NAND flash memory cell array. Data is supplied via the data-out line 972 from the sense amplifiers in block 966 to input/output ports on the integrated circuit 975, or to other data destinations internal or external to the integrated circuit 975.

A controller implemented in this example using bias arrangement state machine 969 controls the application of bias arrangement supply voltage generated or provided through the voltage supply or supplies in block 968, such as read, erase, program, erase verify and program verify voltages. The controller can be implemented using special-purpose logic circuitry as known in the art. In alternative embodiments, the controller comprises a general-purpose processor, which may be implemented on the same integrated circuit, which executes a computer program to control the operations of the device. In yet other embodiments, a combination of special-purpose logic circuitry and a general-purpose processor may be utilized for implementation of the controller.

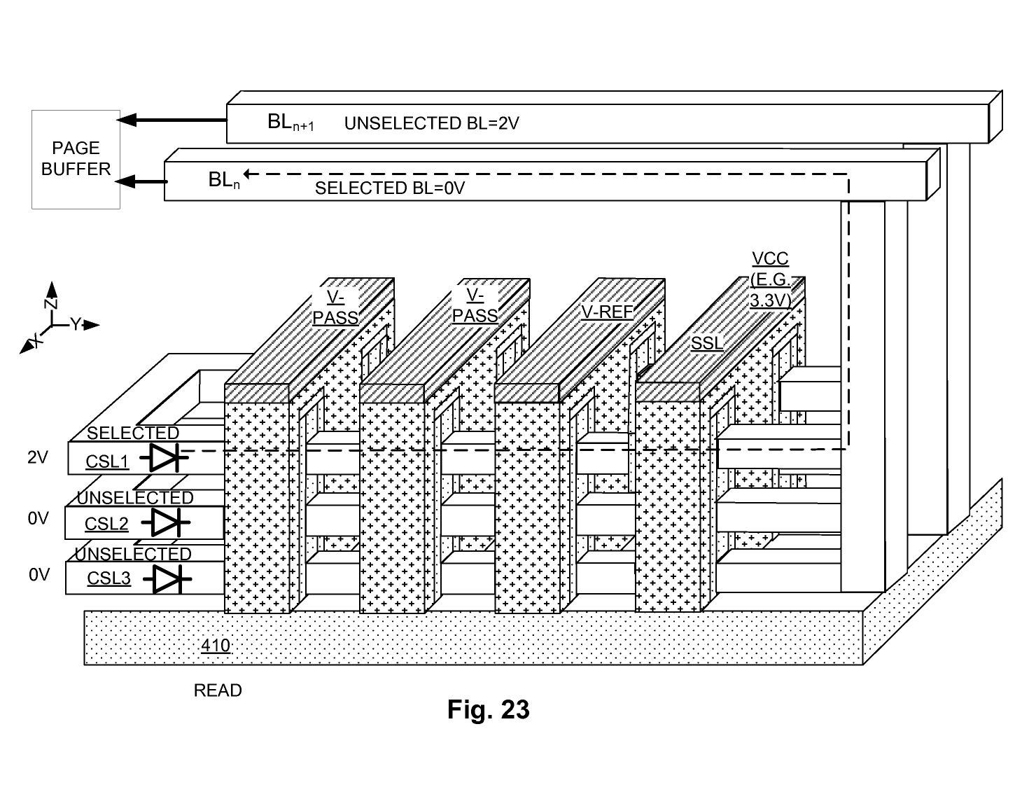

FIG. 19 is a TEM cross-section of a portion of an 8-layer vertical gate, thin-film-transistor, BE-SONOS charge trapping NAND device which has been fabricated and tested, arranged for decoding as shown in FIGS. 8 and 23. The device was made with a 75 nm half pitch. The channels were n-type polysilicon about 18 nm thick. No additional junction implant was used, resulting in a junction free structure. The insulating material between the strips to isolate the channels in the Z-direction was silicon dioxide was about 40 nm thick. The gates were provided by a p+-polysilicon line. The SSL devices had longer channel lengths than the memory cells. The test device implemented 32 word line, junction-free NAND strings. The width of the lower strip in FIG. 19 is greater than the width of the upper strip because the trench etch used to form the structure resulted in a tapered side wall with progressively wider strips as the trench becomes deeper, and with the insulating material between the strips being etched more than the polysilicon.

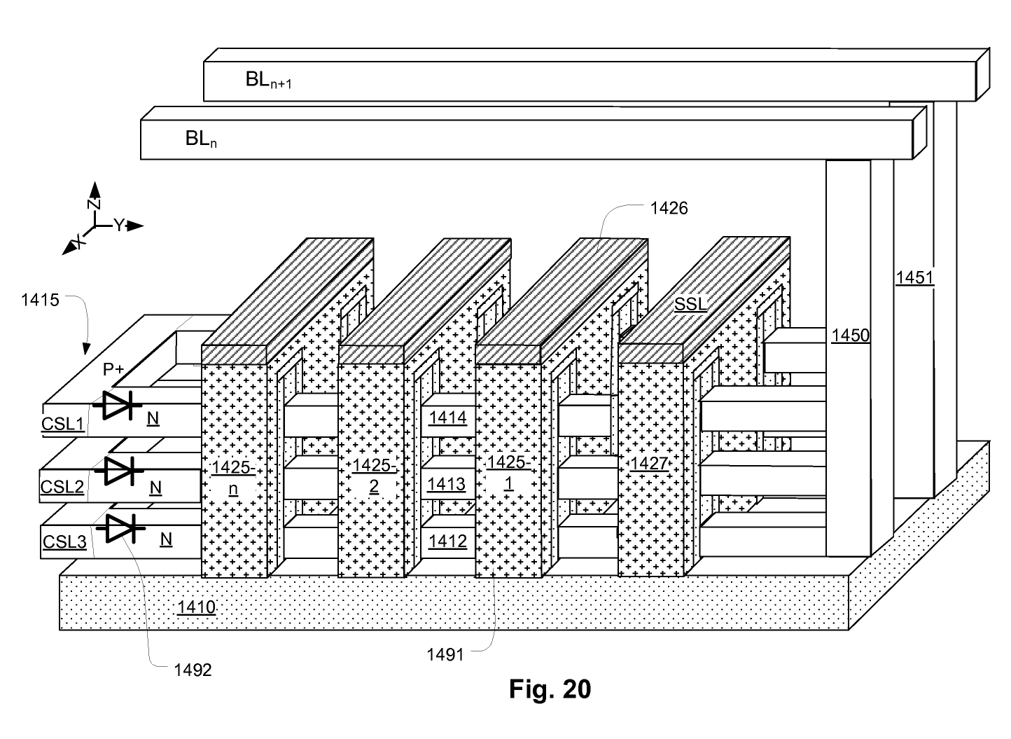

FIG. 20 illustrates a perspective embodiment including diodes (e.g. diode 2592) on the common source line end of the NAND strings in the semiconductor bodies. The structure includes a plurality of ridge shaped stacks including the semiconductor material strips 1414, 1413, 1412 in respective planes of the ridge shaped stacks on a substrate 1410. A plurality of conductive lines 1425-1, 1425-2, to 1425-n (only three are shown for simplicity in this diagram) act as word lines which extend orthogonally across the stacks, and are conformal over memory layers as described above. Conductive line 1427 acts as a string select line (SSL) and such lines are arranged parallel to the plurality of conductive lines acting as word lines. These conductive lines are formed by conductive material 1491, such as polysilicon having n-type or p-type doping, to be used for the conductive lines which act as word lines. Silicide layers 1426 can overlie the tops of the conductive lines acting as word lines and string select lines.

In the region 1415, the semiconductor material strips 1414, 1413, 1412 are connected to the other semiconductor material strips in the same planes by common source line interconnections, and to a plane decoder (not shown). Diodes (e.g. 1492) are placed between the common source lines (CSL1, CSL2, CSL3) and the memory cells coupled to the word lines 1425-1 through 1425-n. In the region 1415 the n-type source line ends of the semiconductor material strips in each plane are coupled together by a P+ line or implants, forming PN diodes on the source line end of each memory string between the common source lines and the word lines. The semiconductor material strips are extended in the common source line interconnections using a stepped contacting area.

At the bit line ends of the semiconductor material strips, plugs 1450, 1451 couple the semiconductor material strips 1414, 1413, 1412 to bit lines BLn, BLn+1. Plugs 1450, 1451 can comprise doped polysilicon, tungsten or other vertical interconnect technologies. Overlying bit lines BLn, BLn+1 are connected between the plugs 1450, 1451 and column decoding circuitry (not shown). SLs source lines of each layer are separately decoded. SSL string select line, WL's word lines, and BL's bit lines are common vertically for the multilayer stacks. In the structure shown in FIG. 20, no contacts need to be formed in the array to be string select gates and common source select gates.

Various embodiments of the structure of FIG. 20 employ source-side (source line) reverse sensing. In various embodiments, the diode suppresses stray current paths during read and program inhibit operations.

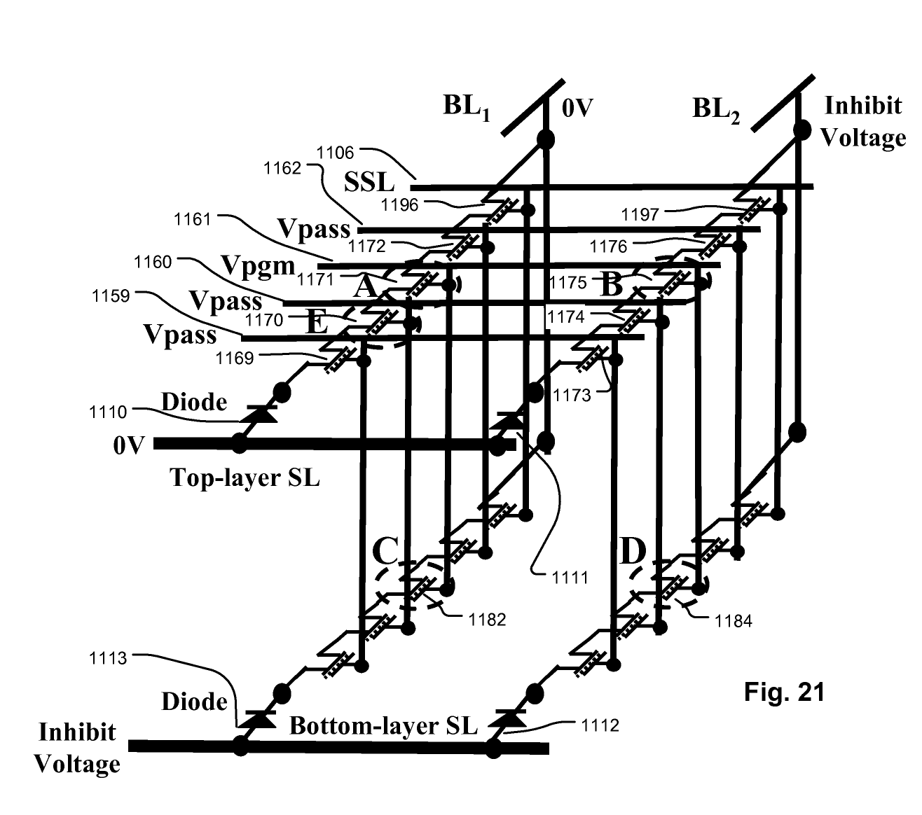

FIG. 21 is a schematic diagram showing 2 planes of memory cells having 6 charge trapping cells arranged in a NAND configuration, which is representative of a cube which can include many planes and many word lines. The 2 planes of memory cells are defined at the cross-points of conductive lines 1159, 1160, 1161, 1162 acting as word lines, with a first stack of semiconductor material strips and a second stack of semiconductor material strips.

The first plane of memory cells is a top plane in this example, and includes memory cells 1169, 1170, 1171, 1172 in a NAND string on a semiconductor material strip, and memory cells 1173, 1174, 1175, 1176 in a NAND string on another semiconductor material strip. The second plane of memory cells corresponds with a bottom plane in this example, and includes memory cells (e.g. 1182, 1184) arranged in NAND strings in a manner similar to those in the first plane.

As shown in the figure, the conductive line 1161 acting as word line WLn includes vertical extensions which correspond with the material in the trench 120 shown in FIG. 5 between the stacks, in order to couple the conductive line 1161 to the memory cells (cells 1171, 1175 in the first plane) in the interface regions in the trenches between the semiconductor material strips in all of the planes.

String select transistors 1196, 1197 are connected between respective NAND strings and corresponding bit lines BL1 and BL2 in this arrangement. Likewise, similar string select transistors on a bottom plane are connected between respective NAND strings and corresponding bit lines BL1 and BL2 in this arrangement, so that column decoding is applied to the bit lines. String select line 1106 is connected to the string select transistors 1196, 1197, and arranged parallel to the word lines, as illustrated in FIG. 20.

Diodes 1110, 1111, 1112, 1113 are connected between the strings and corresponding source lines in this example. The diodes 1110, 1111, 1112, 1113 couple a NAND string in a particular layer to a common source reference line. This diode position supports program inhibit.

The common source reference lines are decoded by a plane decoder. The string select transistors can use the same dielectric stack as a gate oxide as the memory cells in some embodiments. In other embodiments, a typical gate oxide is used instead. Also, the channel lengths and widths can be adjusted as suits the designer to provide the switching function for the transistors. A description of a programming operation is provided, where the target cell is cell A in FIG. 21, and the program disturb conditions are considered for cell B, representing cells on the same plane/source line and the same row/word line but different column/bit line as the target cell, for cell C, representing cells on the same row/word line and a same column/bit line but different plane/source line as the target cell, for cell D, representing cells on the same row/word line as the target cell but on a different column/bit line and a different plane/source line than the target cell, and for cell E, representing cells on the same plane/source line and same column/bit line but different row/word line as the target cell.

According to this arrangement, the string select lines are decoded on a block by block basis. The word lines are decoded on a row by row basis. The common source lines are decoded on a plane by plane basis. The bit lines are decoded on a column by column basis.

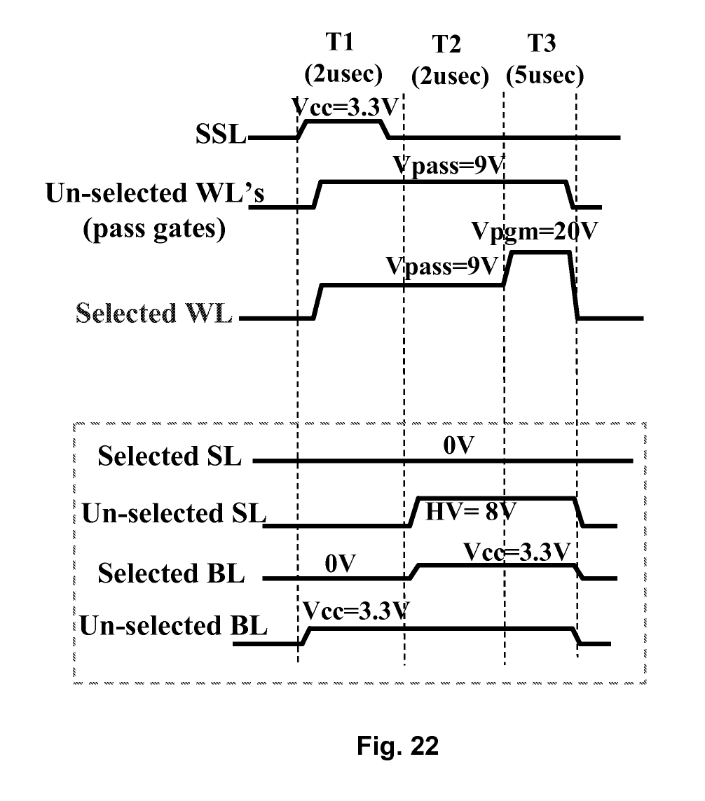

FIG. 22 is a timing diagram for a programming operation in an array like that of FIG. 20.

T3: Start to program Cell A. The inversion channel was already formed during T1 phase.

FIG. 22 is a timing diagram for an example of a programming operation in an array like that of FIG. 21. The program interval is divided into three primary segments labeled T1, T2 and T3.

During time phase T1, unselected BLs bit lines are self-boosted (cells B and D) by Vcc voltage on SSL string select lines and Vcc voltage on unselected BLs bit lines. The channel voltage Vch is boosted for memory cells B and D.

During time phase T2, the unselected SLs source lines are raised to HV high voltage. The Vch channel voltage is raised directly for memory cells coupled to unselected SLs source lines, such as cell C. The already boosted Vch channel voltage of cell B does not leak out through the source line SL, due to the diode at the SL source line which is reverse-biased with low leakage, when source line SL=0V and the bit lines BLs=3.3V.

During time phase T3, cell A is programmed. The inversion channel was already formed during time phase T1. While cell A is programmed, the respective boosted Vch channel voltages of memory cells B, C, and D prevent programming of memory cells B, C, and D.

A read bias condition suitable for the structure of FIG. 20 is shown in FIG. 23. According to the bias condition of the structure on substrate 410 shown in FIG. 23, a plane of cells is biased for reading by applying pass voltages to unselected word lines, and a read reference voltage to a selected word line. The selected common source line is coupled to about 2 V, unselected common source lines are coupled to about 0V, while the string select line SSL is coupled to about 3.3 V. The selected bit line BLn and is coupled to about 0V, and the unselected bit line BLn+1 is coupled to a precharge level of about 2 V. The precharge voltage of 2V in the unselected bit line prevents stray read current from flowing into the unselected bit line from the selected source line.

Page decoding in this example can be accomplished using the common source line, plane decoding. Thus, for a given read bias condition a page having the same number of bits as there are bit lines can be read for each selected common source line, or plane, in the 3D array. The selected common source line is set at a reference voltage of about 2V, while the other common source lines are set to about 0 V. The diodes in the bit line paths for the unselected planes prevent stray current.

In a page read operation, each word line is read one time for each plane in the cube. Likewise, during a program operation operated on a page basis the program inhibit conditions must be sufficient to endure the number of programming operations required for the page, that is one for each plane. Therefore for a block including eight planes of memory cells, the program inhibit conditions must endure eight cycles of program for unselected cells.

It is noted that the diode in the bit line string requires that the bias on the source line be increased slightly to compensate for the diode junction drop which is typically about 0.7 V.

In the read operations of FIGS. 22 and 23, each source line SL applies a certain positive voltage, to perform a source-side read (or reverse read). So the source lines SLs are distinct from a ground line GL which stays at a ground voltage.

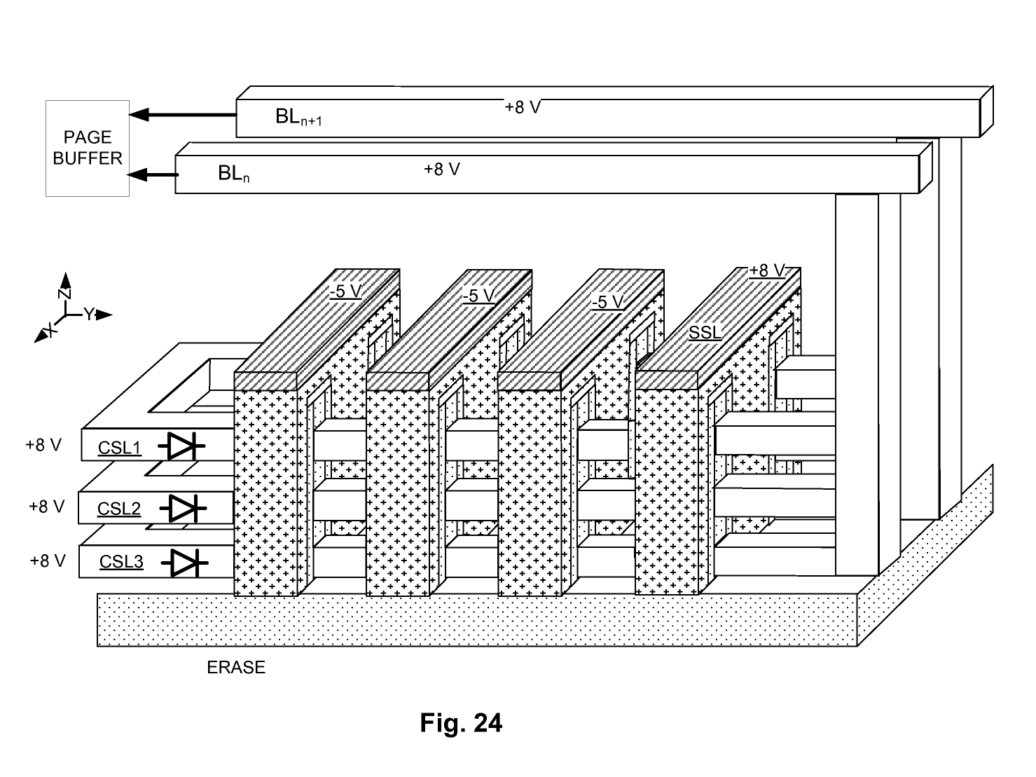

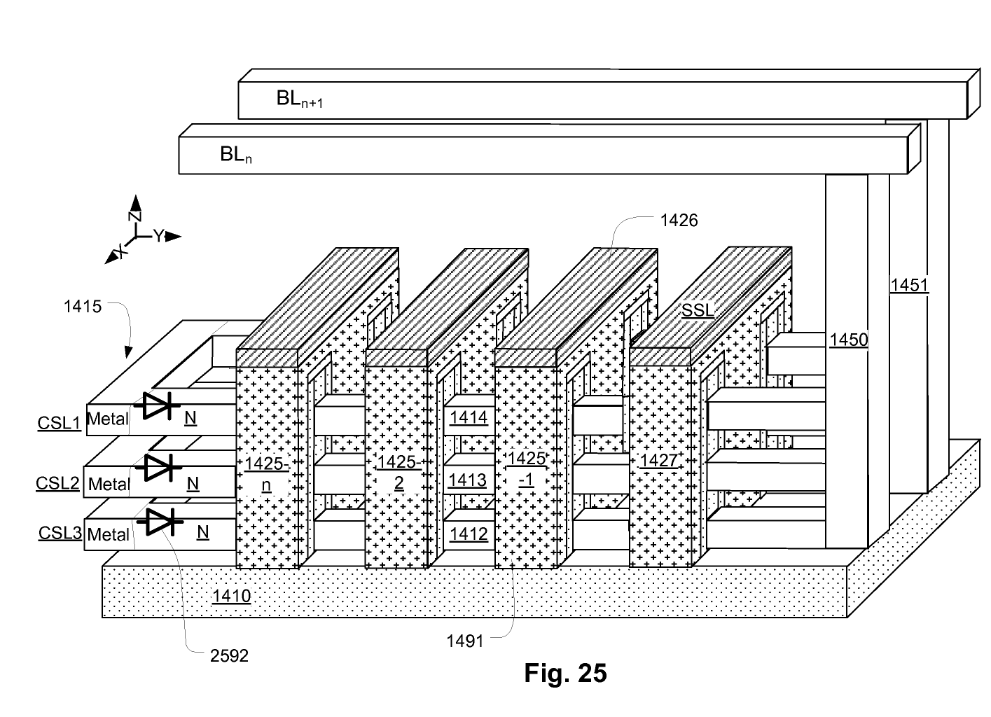

FIG. 24 illustrates the biasing conditions for a block erase operation. In the arrangement shown in the figure, the word lines are coupled to a negative voltage such as about −5 V, the common source lines and bit lines are coupled to a positive voltage of about +8 V, and the SSL string select line is coupled to a suitably high pass voltage, such as about +8 V. This helps suppress the punch-through criterion of the source line bias. Other blocks' SSL are turned off. The high voltage requirement of the BL is satisfied by BL driver design. Alternatively, the word lines and string select line can be grounded while the common source lines are coupled to a high-voltage such as 13 V.

During self-boosting, the PN diodes have to sustain a boosted channel potential ˜8V within several tens of microseconds. The estimated leakage current of reverse bias at 8V should be smaller than 100 pA to sustain the boosted potential. Of course, the breakdown should be much higher than 8V. A low turn-on voltage (e.g., <0.7 V) helps prevent sensing difficulties.

FIG. 25 is a perspective view of a 3D NAND-flash memory structure including Schottky diodes in the strings between the source line structures and the memory strings. In this embodiment, rather than semiconductor p-n junctions, the diodes 2592 are Schottky metal-semiconductor diodes. Metal silicide formed at the source line end forms a Schottky diode. Metal silicide has much lower resistance than silicon, reducing the source line resistance. Example silicide materials are Pt, Ni, Ti, and Co. With careful processing work, a sufficient barrier height with respect to the band diagram of the Schottky device barrier maintains a high ON/OFF ratio at the metal/silicon junction. The Schottky barrier has a breakdown voltage, such as over 8V magnitude at reverse bias.

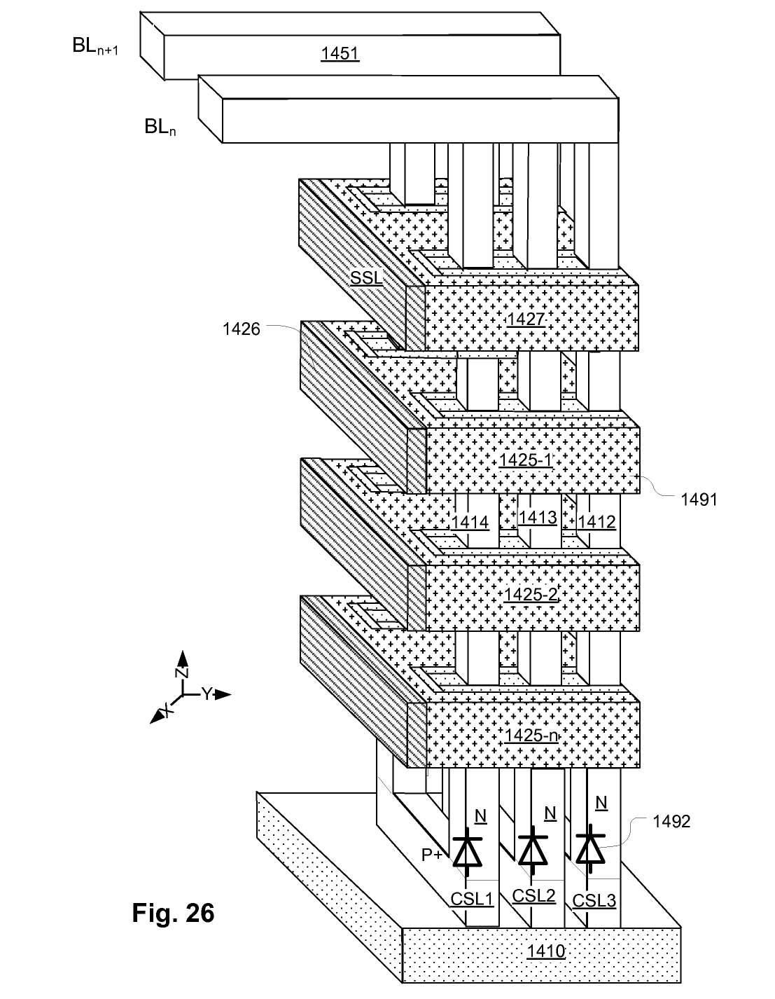

FIG. 26 is a perspective view of a vertical channel version of a 3D NAND-flash memory structure including diodes in the strings between the source line structures and the memory strings.

The vertical channel 3D array resembles the horizontal channel 3D array of FIG. 21, rotated by 90 degrees. IN the vertical channel 3D array, the semiconductor material strips of the NAND strings extend perpendicularly out of the substrate 1410. Each of the source lines CSL1, CSL2, CSL3 are electrically separated from each other.

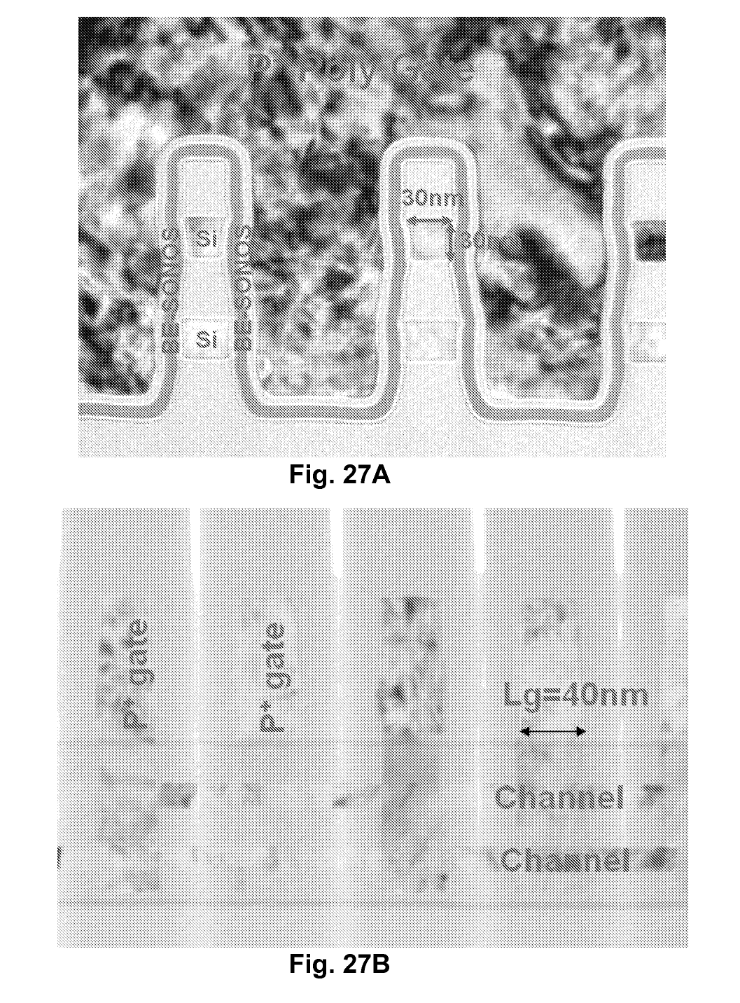

FIGS. 27A and 27B are transmission electron microscope TEM images of a portion of 3D NAND-flash memory array.

Shown are the TEM pictures of the 75 nm half pitch (4F2) VG devices. The channel width and length are 30 and 40 nm, respectively, while channel height is 30 nm. Each device is a double-gate (vertical gate) horizontal-channel device, where channel doping is lightly-doped n-type (buried-channel device) in order to increase the read current. The BL bit line profile is optimized to make a planar ONO topology. A small sidewall recess is obtained by optimizing the processing. Very planar ONO is deposited at the sidewall of BL bit line.

FIG. 27A is an X-direction cross-sectional view of the array. Charge-trapping BE-SONOS devices are grown on the two sides of each channel. Each device is a double-gate device. Channel current flows horizontally, while the gate is vertically common. The sidewall ONO recess is minimized.

FIG. 27B is a Y-direction cross-sectional view of the array. Due to the tight pitch and small bit line (BL) width, the FIB focused ion beam TEM transmission electron microscopy image shows double images including poly gate landing at the BL's line (horizontal semiconductor strip) and space. The channel length is around 40 nm in the shown device.

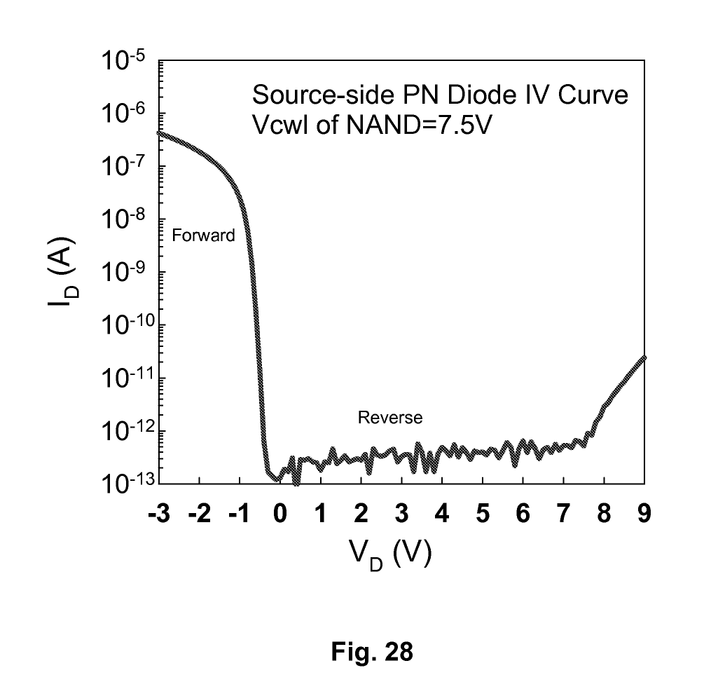

FIG. 28 is a graph of IV characteristics of experimentally measured PN diodes.

The forward and reverse IV characteristic of polysilicon PN diodes are measured directly in the PN diodes connected in the VG vertical gate 3D NAND array. The polysilicon height/width dimensions are 30 nm/30 nm. The reverse leakage is much lower than 10 pA at 8V reverse bias, which helps eliminate the stray read current paths. is already sufficient for the self-boosting requirement and program disturb. The reverse breakdown voltage magnitude is greater than 8V reverse bias, which is sufficient for self-boosting of the channel voltage to inhibit programming of nearby unselected memory cells while programming a selected memory cell. The drain bias Vd is applied, and the Vpass voltage of 7.5 V (shown as Vcwl or control word line) is applied to all WLs word lines and the SSL string select lines. The P+-N diode (30 nm width and 30 nm height) shows successful ON/OFF ratio of more than 5 orders of magnitude. The diode forward turn on voltage magnitude is about 0.8V. The forward diode current saturates, being clamped by the NAND string serial resistance.

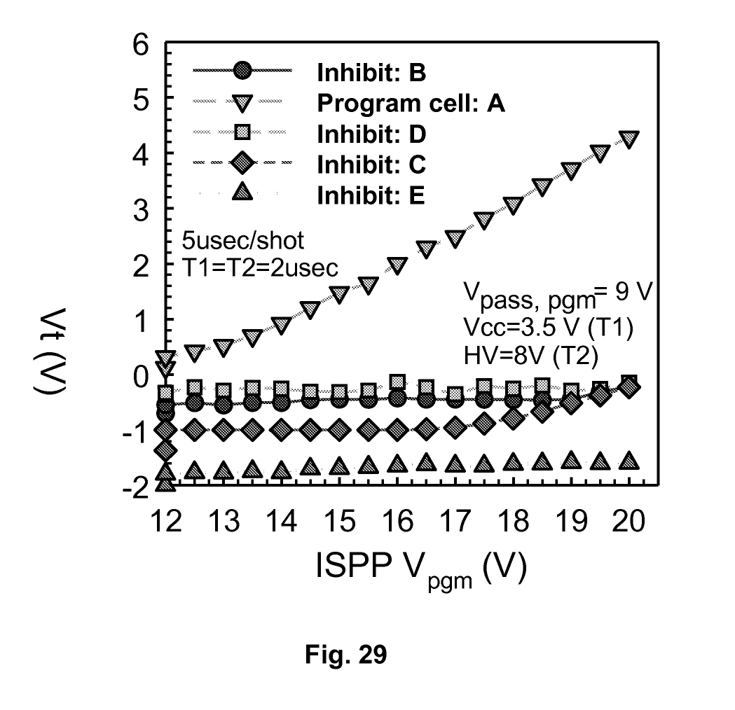

FIG. 29 is a graph of the program inhibit characteristics of experimentally measured polysilicon diode connected 3D NAND memory.

Typical program inhibit characteristics of Cells A, B, C, D are shown. These experimental results are based on the three phase programming (T1, T2, T3) described at FIG. 22. Vcc=3.5V, HV=8V, Vpass=9V in this case. The ISPP (with stepping bias) method is applied at Cell A. The graph shows a disturb-free window larger than 4V. This is a product of the diode isolation property.

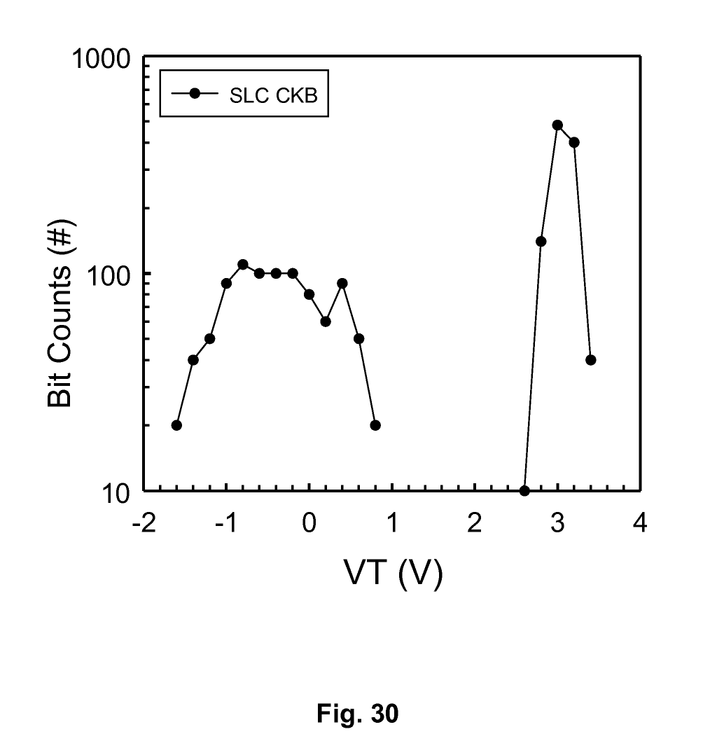

FIG. 30 is a graph of threshold voltage distribution for experimentally measured pn diode connected 3D NAND memory having a checkerboard distribution of programmed/erased memory cells.

A SLC (single level cell) checkerboard CKB distribution was used for the PN diode decoded 3D memory array. Nearest neighbor (in the 3-dimensional sense) cells were programmed to the opposite state for the worst-case disturb. Conventional page programming and program inhibit (Cell B conditions) methods are carried out in each layer, and then the other unselected source lines (Cell C and D) inhibited. Page programming is conducted on the other layers subsequently. Unselected cells suffer many sources of row stress and column stress in a 3D array.

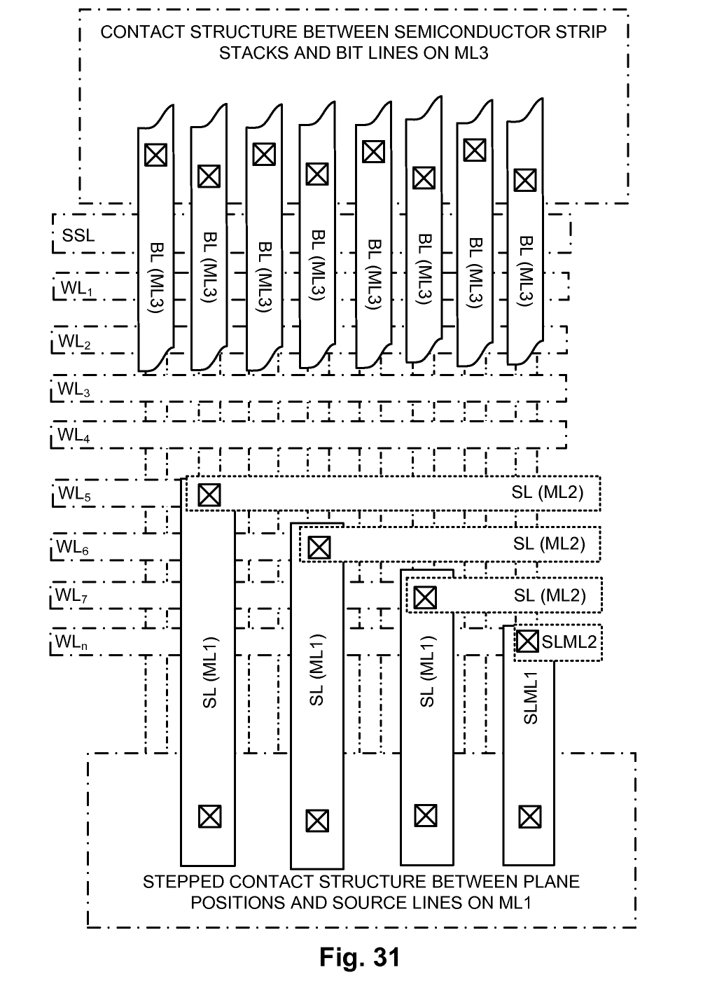

FIG. 31 is a layout view of a 3D NAND-flash memory array structure including diodes in the strings between the source line structures and the memory strings.

In the layout view of FIG. 31, the stacks of semiconductor strips are shown as vertical strips with dot-short dash borders. The stacks of semiconductor strips run from the bit line contact structure at the top, to the source line contact structure at the bottom.

Overlying the stacks of semiconductor strips, are the horizontal word lines and the horizontal SSL string select line, both shown as horizontal strips with dot-long dash borders. The SSL string line controls select transistor devices that provide a selectable electrical connection between any stack of semiconductor strips and the stack's corresponding bit line contact structure. The shown word lines are numbered from 1 to N and are electrically controlled by a word line decoder. In one embodiment, there are 64 word lines per block, and other embodiments contain different numbers of word lines.

Overlying the word lines, and SSL string select line are the ML1 SL source lines running vertically. A stepped contact structure is at the bottom of the figure. This electrically couples the different ML1 SL source lines to different plane positions of the stacks of NAND memory cell strings. Although the ML1 SL source lines are shown as terminating at corresponding ML2 SL source lines and at the stepped contact structure, for ease of viewing the structure, the ML1 SL source lines may run longer.

Overlying the ML1 SL source lines are the ML2 SL source lines running horizontally The ML2 SL source lines carry signals from a decoder, and the ML1 SL source lines couple these decoder signals to particular plane positions of the stacks of NAND memory cell strings. Although the ML2 SL source lines are shown as terminating at corresponding ML1 SL source lines for ease of viewing the structure, the ML2 SL source lines may run longer.

As shown, there are four ML2 SL source lines and four ML1 SL source lines. These are sufficient to electrically couple to four plane positions. Four plane positions are provided by four NAND memory cell strings in each stack of NAND memory cell strings. The NAND memory cell string at the same stacked position across all the stacks are in the same plane position. Other embodiments may include a different number of plane positions with a corresponding number of NAND memory cell strings in each stack of NAND memory cell strings, and with a corresponding number of ML2 SL source lines and ML1 SL source lines.

Overlying the ML2 SL source lines are the ML3 bit lines which connect to the contact structures at the top of the figure. The tightly pitched bit lines are electrically coupled to different stacks of semiconductor strips. As shown, there are eight ML3 BL bit lines. These are sufficient to electrically couple to eight stacks of NAND memory cell strings. Other embodiments may include a different number of stacks.

The layout of FIG. 31 can be mirrored about the top contact structure and/or the bottom contact structure. In the layout, one example half pitch in the X and Y directions is 42 nm. The Y direction dimensions are provided as follows, in order from the top of the figure to the bottom of the figure. Half of the bit line contact structure is about 0.2 um. The SSL channel length is 0.25 um. The word lines, in the case of 64 word lines, are 2.668 um. The distance from the bottom-most word line to the bottom source line contact structure is 0.3 um. Half of the source line contact structure is 0.2 um.

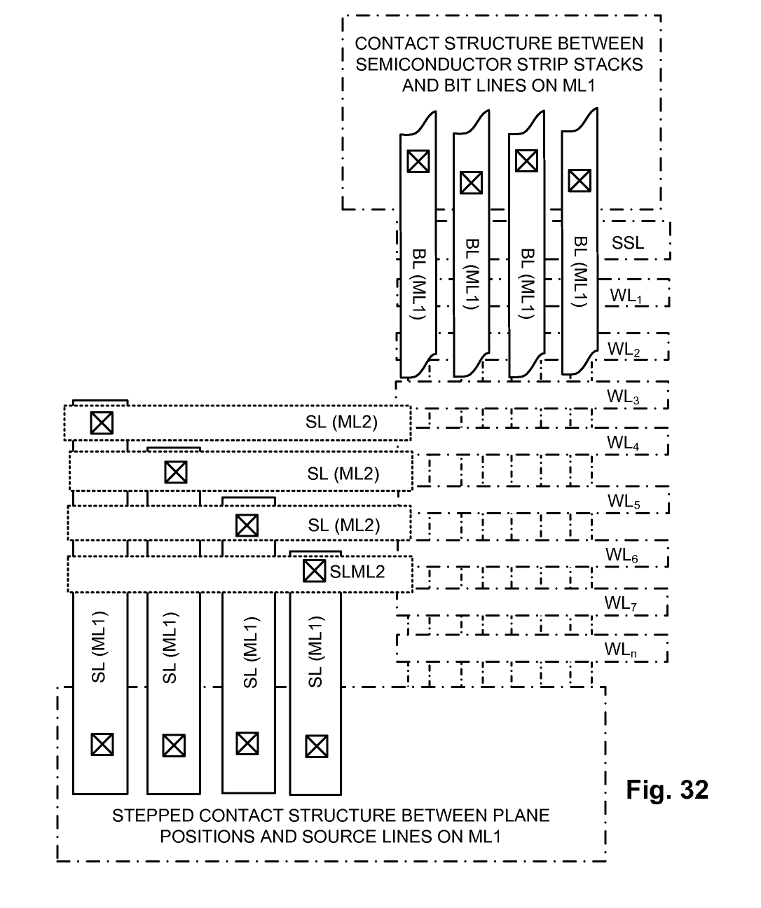

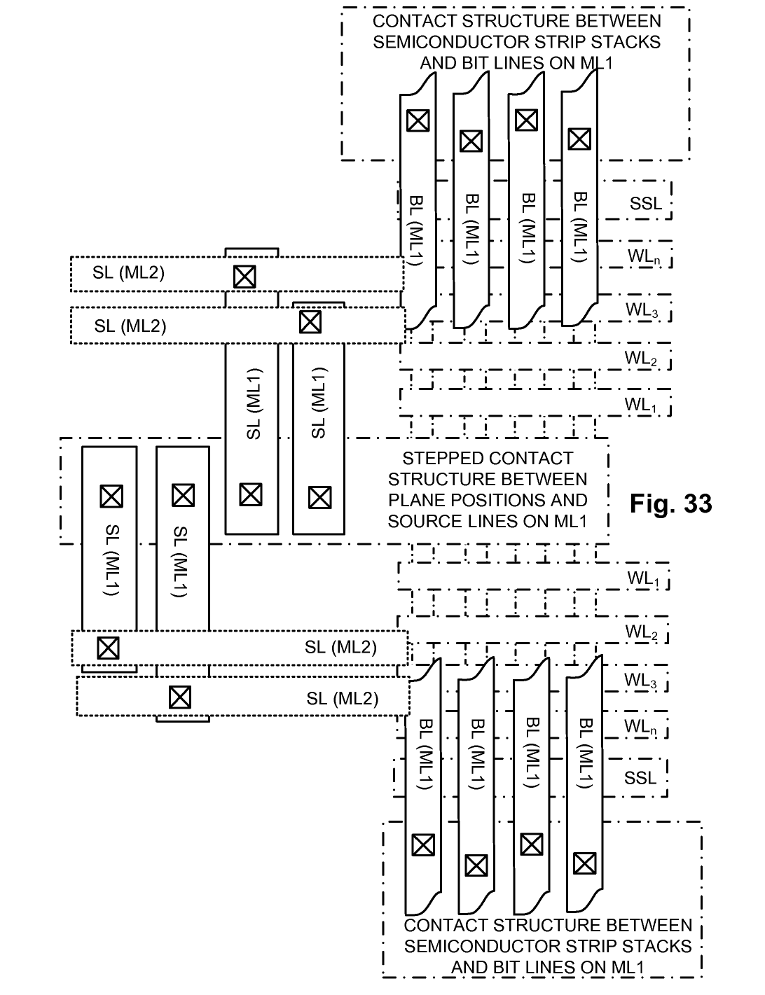

FIG. 32 is another layout view of a 3D NAND-flash memory array structure including diodes in the strings between the source line structures and the memory strings.

The FIG. 32 layout is similar to FIG. 31. Unlike the layout of FIG. 31, in FIG. 32 the bit lines BL are on the same metal layer ML1 as the source lines SL, such that both the bit lines BL and the lower layer of source lines SL run in the same vertical direction in the figure. The upper layer of source lines SL overlies both the bit lines BL and the lower layer of source lines higher metal layer ML2. The source lines SL on the metal layer ML2 are all to one side of the source line contact structure, in this case all above the source line contact structure. The shown SL source line strapping between the metals layers ML2 and ML1 occurs in the horizontal direction of the figure every 256 bit lines BL. The shown SL source line strapping occupies an overhead of about 16 bit lines BL.

FIG. 33 is yet another layout view of a 3D NAND-flash memory array structure including diodes in the strings between the source line structures and the memory strings.

The FIG. 33 layout is similar to FIG. 32. Unlike the layout of FIG. 32 where the source lines SL on the metal layer ML2 are all to one side of the source line contact structure, in FIG. 33 the source lines SL on the metal layer ML2 are divided between both sides of the source line contact structure. Source lines for the two adjacent blocks are shared, as shown. Additional blocks above and below the shown blocks have source lines SL independent of the shown source lines SL.

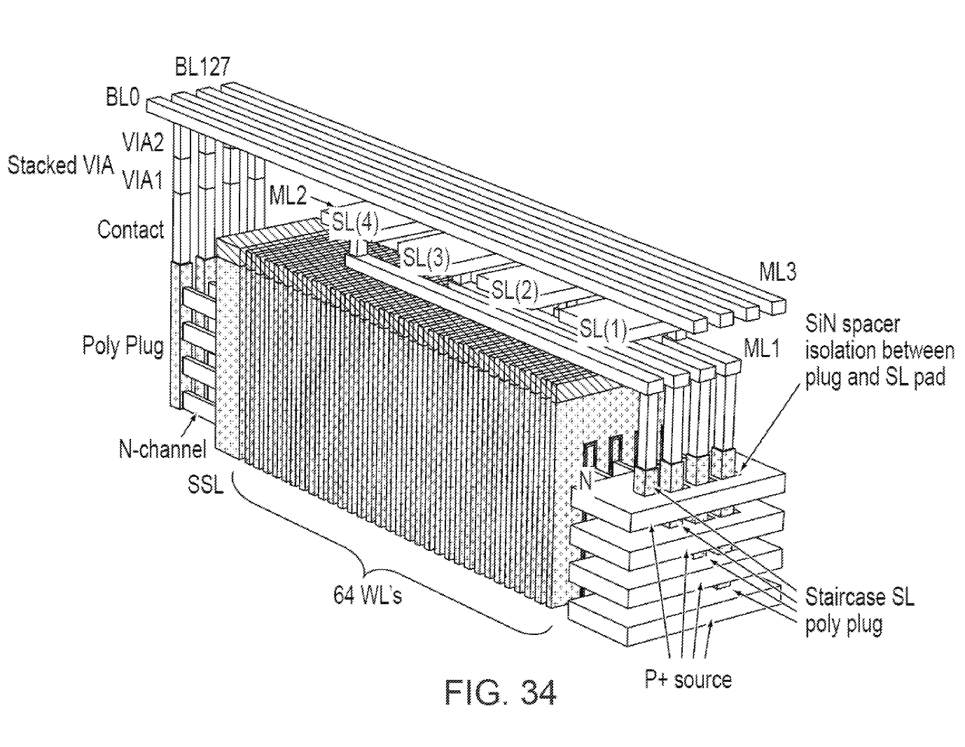

FIG. 34 is a perspective view of a 3D NAND-flash memory structure including diodes in the strings between the source line structures and the memory strings.

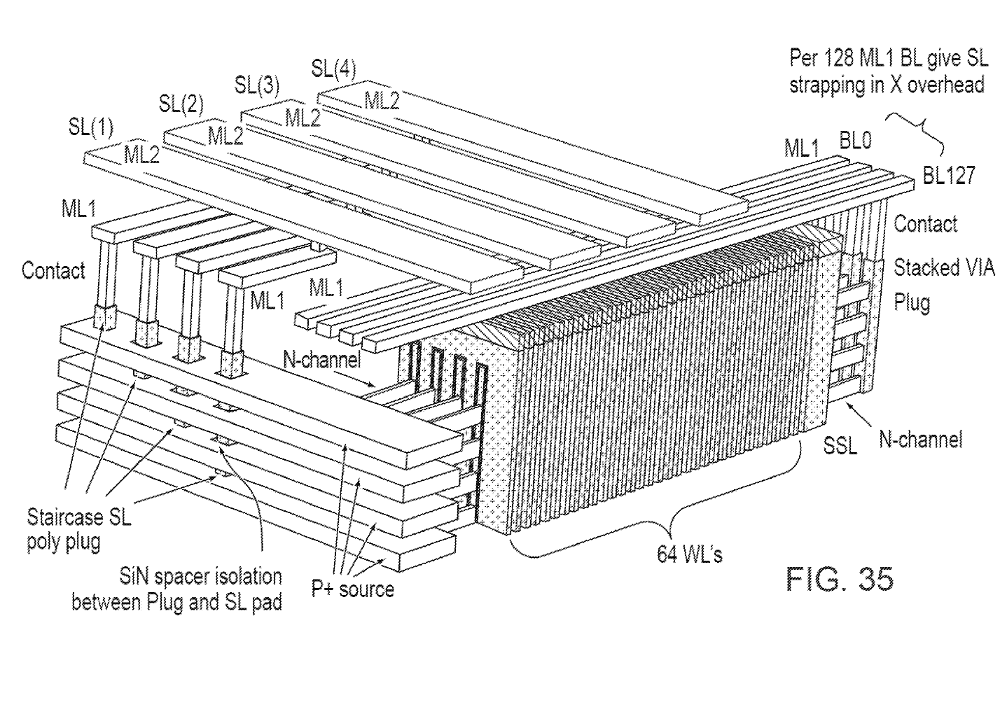

FIG. 35 is another perspective view of a 3D NAND-flash memory structure including diodes in the strings between the source line structures and the memory strings.

In both FIGS. 34 and 35, the GSL ground select line is absent between the WL word lines and the source line contact structures, and GSL ground select line-controlled devices are absent between the WL word lines and the source line contact structure.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A memory device, comprising:
an integrated circuit substrate;
a 3D array of nonvolatile memory cells on the integrated circuit substrate, the 3D array including:
stacks of NAND strings of nonvolatile memory cells having two ends including a first end and a second end, one of the first end and the second end coupled to bit lines, and the other of the first end and the second end coupled to source lines;
a select line only at the first end of the NAND strings and not by the second end of the NAND strings, the select line electrically selectively coupling the NAND strings to one of the bit lines and the source lines, the select line arranged orthogonally over, and has surfaces conformal with, the stacks; and
diodes coupling the strings of memory cells to the other of the bit lines and the source lines, such that the select line and the diodes are at opposite ends of the NAND strings.

2. The device of claim 1, further comprising:
a plurality of word lines arranged orthogonally over, and having surfaces conformal with, the plurality of stacks, the plurality of word lines establishing the nonvolatile memory cells at cross-points between surfaces of the plurality of stacks and the plurality of word lines,
wherein the select line is positioned between one of the bit lines and the source lines, and the plurality of word lines.

3. The device of claim 1, wherein the source lines are electrically coupled to different horizontal plane positions of the stacks of NAND strings of nonvolatile memory cells.

4. The device of claim 1, wherein the bit lines are electrically coupled to different ones of the stacks of NAND strings of nonvolatile memory cells.

5. The device of claim 1, wherein the diodes are semiconductor p-n junctions.

6. The device of claim 1, wherein the diodes are Schottky metal-semiconductor junctions.

7. The device of claim 1, wherein the memory cells have interface regions between the stacks and word lines, the interface regions including a tunneling layer, a charge trapping layer and a blocking layer.

8. The device of claim 1, wherein a first material of the source lines form first node of the diodes and a second material of the stacks of NAND strings form second nodes of the diodes.

9. A memory device, comprising:
an integrated circuit substrate;
a 3D array of nonvolatile memory cells on the integrated circuit substrate, the 3D array including:
stacks of NAND strings of nonvolatile memory cells having two ends including a first end and a second end, one of the first end and the second end coupled to bit lines, and the other of the first end and the second end coupled to source lines;
select devices only at the first ends of the NAND strings and not at the second ends of the NAND strings, the select devices electrically selectively coupling the NAND strings to one of the bit lines and the source lines; and
diodes coupling the strings of memory cells to the other of the bit lines and the source lines, such that the select line and the diodes are at opposite ends of the NAND strings.

10. The device of claim 9, further comprising:
a plurality of word lines arranged orthogonally over, and having surfaces conformal with, the plurality of stacks, the plurality of word lines establishing the nonvolatile memory cells at cross-points between surfaces of the plurality of stacks and the plurality of word lines,
wherein the select devices are positioned between one of the bit lines and the source lines, and the memory devices established by the plurality of word lines.

11. The device of claim 9, wherein the source lines are electrically coupled to different horizontal plane positions of the stacks of NAND strings of nonvolatile memory cells.

12. The device of claim 9, wherein the bit lines are electrically coupled to different ones of the stacks of NAND strings of nonvolatile memory cells.

13. The device of claim 9, wherein the diodes are semiconductor p-n junctions.

14. The device of claim 9, wherein the diodes are Schottky metal-semiconductor junctions.

15. The device of claim 9, wherein the memory cells have interface regions between the stacks and word lines, the interface regions including a tunneling layer, a charge trapping layer and a blocking layer.

16. The device of claim 9, wherein a first material of the source lines form first node of the diodes and a second material of the stacks of NAND strings form second nodes of the diodes.

17. A memory device, comprising:
an integrated circuit substrate;
a 3D array of nonvolatile memory cells on the integrated circuit substrate, the 3D array including:
stacks of NAND strings of nonvolatile memory cells having two ends including a first end coupled to bit lines and a second end coupled to source lines;
diodes coupling the strings of memory cells to the source lines, wherein only the diodes provide current flow control between the source lines and the second end of the stacks of NAND strings.

18. The device of claim 17, further comprising:
a plurality of word lines arranged orthogonally over, and having surfaces conformal with, the plurality of stacks, the plurality of word lines establishing the nonvolatile memory cells at cross-points between surfaces of the plurality of stacks and the plurality of word lines; and
select devices at the first ends of the NAND strings by the bit lines, the select devices electrically selectively coupling the NAND strings to the bit lines; and
wherein the select devices are positioned between the bit lines and the memory devices established by the plurality of word lines.

19. The device of claim 17, wherein the source lines are electrically coupled to different horizontal plane positions of the stacks of NAND strings of nonvolatile memory cells.

20. The device of claim 17, wherein the bit lines are electrically coupled to different ones of the stacks of NAND strings of nonvolatile memory cells.

21. The device of claim 17, wherein the diodes are semiconductor p-n junctions.

22. The device of claim 17, wherein the diodes are Schottky metal-semiconductor junctions.

23. The device of claim 17, wherein the memory cells have interface regions between the stacks and word lines, the interface regions including a tunneling layer, a charge trapping layer and a blocking layer.

24. The device of claim 17, wherein a first material of the source lines form first node of the diodes and a second material of the stacks of NAND strings form second nodes of the diodes.

25. A method of operating a 3D NAND nonvolatile memory, including:
applying a program bias arrangement sequence to NAND strings in the 3D NAND nonvolatile memory such that diodes are coupled between the NAND strings of memory cells and source lines, wherein the diodes preserve a boosted channel of the NAND strings without relying on select devices between the NAND strings and the source lines.
